(19) United States
(12) Patent Application Publication
(10) Pub. No.: US 2026/0214906 A1
(43) Pub. Date: Jul. 23, 2026

(54) SEMICONDUCTOR DEVICES HAVING CAPACITOR STRUCTURES

(71) Applicant: Samsung Electronics Co., Ltd., Suwon-si (KR)

(72) Inventors: Seungmin Lee, Suwon-si (KR); Minkyu Kang, Suwon-si (KR); Kangin Lee, Suwon-si (KR); Joonsung Lim, Suwon-si (KR); Jieun Ha, Suwon-si (KR); Sekwon Hong, Suwon-si (KR)

(21) Appl. No.: 19/419,269

(22) Filed: Dec. 15, 2025

(30) Foreign Application Priority Data
Jan. 21, 2025 (KR) 10-2025-0009016

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A semiconductor device includes: a substrate including an active region; transistors including a gate structure; ; a substrate insulating layer; a plurality of capping insulating layers covering the substrate insulating layer and having a flat upper surface; and a capacitor disposed within a capacitor region and penetrating through the plurality of capping insulating layers, and the capacitor includes: a capacitor base extending in a first direction and a second direction,, and having the same plurality of stacked layers as the gate structure; first capacitor electrodes having a plate shape extending in the second direction and a third direction; and second capacitor electrodes having the plate shape, and disposed alternately with the first capacitor electrodes in the first direction, and lower ends of the second capacitor electrodes penetrate through at least some layers of the capacitor base, and lower ends of the first capacitor electrodes penetrate through a lowermost capping insulating layer.

### CROSS-REFERENCE TO RELATED APPLICATION(S)

This application claims benefit of priority to Korean Patent Application No. 10-2025-0009016 filed on Jan. 21, 2025, in the Korean Intellectual Property Office, the disclosure of which is incorporated herein by reference in its entirety.

### BACKGROUND

The present disclosure relates to semiconductor devices having capacitor structures.

Data storage systems requiring data storage require semiconductor devices capable of storing large amounts of data. Accordingly, a method of increasing the data storage capacity of semiconductor devices has been studied. Additionally, highly integrated semiconductor devices are demanded. For example, as one method of increasing the integration of semiconductor devices, a semiconductor device in which memory cells and peripheral circuit regions are disposed vertically has been proposed.

### SUMMARY

An aspect of the present disclosure is to provide a semiconductor device including a capacitor structure having improved integration and electrical characteristics.

However, the object of the present invention is not limited to the above-described objects, and may be variously extended without departing from the spirit and domain of the present disclosure.

A semiconductor device according to example embodiments of the present disclosure includes: a peripheral circuit structure including a substrate, an active region within the substrate, transistors on the substrate, an element isolation region defining the active region, a capping insulating layer covering the transistors, an interconnection wiring electrically connected to the transistors, and a capacitor spaced apart from the interconnection wiring in a first direction; and a memory cell structure including a plate layer disposed on the peripheral circuit structure, gate electrodes sequentially stacked on the plate layer and spaced apart from each other in a second direction, perpendicular to an upper surface of the plate layer, and vertical channel structures penetrating through the gate electrodes and extending in the second direction, wherein the capacitor includes: a capacitor base disposed on the substrate and having multiple layers; first capacitor electrodes having a plate shape extending in a third direction, intersecting the first direction and in the second direction; and second capacitor electrodes, each having a plate shape extending in the second direction and the third direction and disposed alternately with the first capacitor electrodes in the first direction, wherein lower ends of the second capacitor electrodes are disposed to penetrate partially through the capacitor base, and the first capacitor electrodes penetrate through the capping insulating layer so that lower ends of capacitor electrodes of a set of the first capacitor electrodes are disposed at a level higher than an upper surface of the capacitor base.

A semiconductor device according to example embodiments of the present disclosure includes: a substrate including an active region; transistors including a gate structure on the active region, the gate structure including a plurality of stacked layers; an element isolation region defining the active region and defining a capacitor region; a substrate insulating layer covering the transistors and the element isolation region; a plurality of capping insulating layers covering the substrate insulating layer and having a flat upper surface; and a capacitor disposed within the capacitor region defined by the element isolation region and penetrating through the plurality of capping insulating layers, wherein the capacitor includes: a capacitor base extending in a first direction and a second direction, intersecting the first direction, and having the same plurality of stacked layers as the gate structure; first capacitor electrodes having a plate shape extending in the second direction and a third direction, the third direction intersecting the first direction and the second direction; and second capacitor electrodes having the plate shape extending in the second direction and the third direction, and disposed alternately with the first capacitor electrodes in the first direction, wherein lower ends of the second capacitor electrodes are disposed to penetrate partially through the capacitor base, and lower ends of a set of the first capacitor electrodes penetrate through a lowermost capping insulating layer, among the plurality of capping insulating layers, and extend to contact the substrate insulating layer.

A semiconductor device according to example embodiments of the present disclosure includes: a substrate including an active region; a gate structure on the active region; a source/drain region disposed on each of two opposite sides of the gate structure within the active region; an element isolation region defining the active region and defining a capacitor region; a substrate insulating layer covering the gate structure and the element isolation region; a plurality of capping insulating layers covering the substrate insulating layer and having a flat upper surface, the plurality of capping insulating layers including a lowermost capping insulating layer; a first contact plug contacting the gate structure, and a second contact plug contacting the source/drain region, and the first and second contact plugs disposed within the lowermost capping insulating layer; and a capacitor disposed within the capacitor region defined by the element isolation region and penetrating through the plurality of capping insulating layers, wherein the capacitor includes: a capacitor base extending in a first direction and a second direction, intersecting the first direction, and having the same plurality of stacked layers as the gate structure; first capacitor electrodes having a plate shape extending in the second direction and in a third direction, perpendicular to the first direction and the second direction; and second capacitor electrodes having the plate shape extending in the second direction and the third direction and disposed alternately with the first capacitor electrodes in the first direction, wherein lower ends of the second capacitor electrodes are disposed at the same level as lower ends of the first contact plugs, a lower end of a first contact electrode, among the first capacitor electrodes, is disposed at the same level as a lower end of the second contact plug, and a lower end of a second contact pattern, among the first capacitor electrodes, penetrates through the lowermost capping insulating layer on the capacitor base, and extends to contact the substrate insulating layer.

A method of manufacturing a semiconductor device according to example embodiments of the present disclosure includes: forming an element isolation region defining an active region and a capacitor region on a substrate; sequentially stacking and patterning a dielectric layer, a conductive layer and a capping layer within the active region and the capacitor region to form a gate structure on the active region and a capacitor base on the capacitor region, respectively; forming a substrate insulating layer covering the substrate, the gate structure, and the capacitor base; forming a capping insulating layer covering the substrate insulating layer; forming a first opening and a second opening extending from an upper surface of the capping insulating layer to the substrate insulating layer on the capacitor base, extending in a first direction, and spaced apart from each other in a second direction, perpendicular to the first direction; removing the substrate insulating layer from the first opening to expose the conductive layer; and forming subsidiary capacitor electrodes having a plate shape extending in the first direction by filling the first opening and the second opening.

In the forming the substrate insulating layer, the capping insulating layer and a material having etch selectivity may be stacked along a profile of the gate structure and the capacitor base.

The forming the substrate insulating layer may include: forming a first substrate insulating layer covering the gate structure, the capacitor base and the substrate; and forming a second substrate insulating layer covering the first substrate insulating layer and including the first substrate insulating layer and a material having etch selectivity.

The lower end of the second opening may be in contact with the second substrate insulating layer and may be etched to be disposed on a higher level than an upper surface of the first substrate insulating layer.

A depth of the first opening and a depth of the second opening may be formed differently.

A height of the gate structure and a height of the capacitor base may be identical to each other.

The first opening and the second opening may be formed in plural so that first opening and the second opening are spaced apart from each other in the second direction and alternately disposed.

The plurality of first openings and second openings may be formed to be spaced apart from each other by the same separation distance in the second direction.

The forming the first opening may further include forming a first contact opening spaced apart from the capacitor base and extending from the upper surface of the capping insulating layer to the substrate.

A separation distance between the first contact opening and the first opening adjacent thereto may be greater than a separation distance between the first and second openings.

A semiconductor device according to example embodiments of the present disclosure may include a capacitor, and the capacitor may be disposed on a substrate, and lower electrodes having a relatively large height in the vertical direction may be included, thereby securing electrostatic capacitance and providing a semiconductor device having improved electrical characteristics.

In a semiconductor device according to example embodiments, the lower electrodes of the capacitor may extend downwardly to expand the capacitance in ends of the lower electrodes using a substrate insulating layer covering a gate structure and the first peripheral circuit insulating layer as dielectric layers.

Advantages and effects of the present invention are not limited to the foregoing content and may be variously extended without departing from the spirit and domain of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a schematic block diagram of a semiconductor device according to example embodiments of the present disclosure;

FIG. 1B is a circuit diagram illustrating a charge pump circuit included in a voltage generator of a semiconductor device according to example embodiments;

FIG. 1C is a schematic perspective view of a semiconductor device according to example embodiments;

FIG. 2 is a cross-sectional view of a semiconductor device according to example embodiments;

FIG. 3 is a plan view of a semiconductor device according to example embodiments;

FIG. 4 is an enlarged cross-sectional view of a semiconductor device according to example embodiments;

FIG. 5 is a schematic perspective view illustrating an example embodiment of a capacitor structure of a semiconductor device;

FIGS. 6A and 6B are perspective views of a capacitor structure of a semiconductor device according to example embodiments;

FIG. 7 is a schematic perspective view of a capacitor structure of a semiconductor device according to example embodiments;

FIGS. 8 to 10 are enlarged cross-sectional views illustrating example embodiments of a capacitor structure of a semiconductor device;

FIG. 11 is a cross-sectional view illustrating a semiconductor device according to an example embodiment;

FIGS. 12A to 12I are cross-sectional views illustrating a method of manufacturing a semiconductor device according to example embodiments; and

FIG. 13 is a view schematically illustrating a data storage system including a semiconductor device according to example embodiments of the present disclosure.

### DETAILED DESCRIPTION

Hereinafter, example embodiments of the present disclosure will be described with reference to the accompanying drawings. The same reference numerals are used for the same components in the drawings, and duplicate descriptions of the same components are omitted.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (e.g., using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

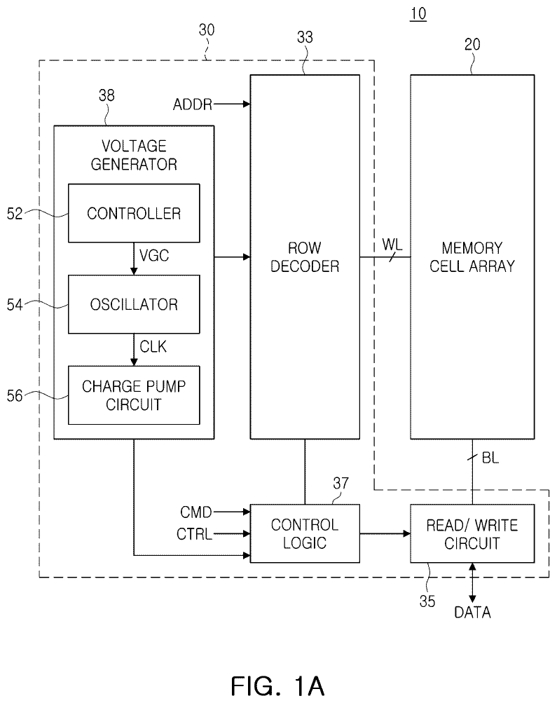

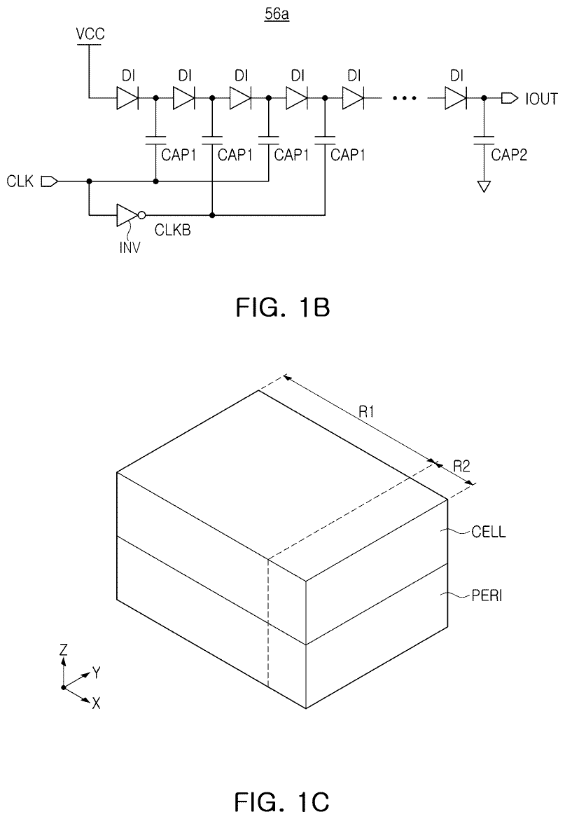

FIG. 1A is a schematic block diagram of a semiconductor device according to example embodiments of the present disclosure, FIG. 1B is a circuit diagram illustrating a charge pump circuit included in a voltage generator of a semiconductor device according to example embodiments, and FIG. 1C is a schematic perspective view of a semiconductor device according to example embodiments.

Referring to FIG. 1A, a semiconductor device 10 may include a memory cell array 20 and a peripheral circuit 30. The semiconductor device 10 may be a memory device, and may be, for example, a nonvolatile memory such as a flash memory or a volatile memory such as a dynamic random access memory (DRAM), a static random access memory (SRAM), or the like.

The memory cell array 20 may include a plurality of memory cells. The plurality of memory cells may be connected to a row decoder 33 through a plurality of word lines WL and may be connected to a read/write circuit 35 through bit lines BL. In one example, a plurality of memory cells arranged on the same row may be connected to the same word line WL, and a plurality of memory cells arranged in the same column may be connected to the same bit line BL. In some example embodiments, the memory cell array 20 may include a plurality of memory blocks, and each of the memory blocks may include a plurality of memory cells.

The peripheral circuit 30 may receive an address ADDR, a command CMD, and a control signal CTRL from an external circuit (the outside of the semiconductor device 10), and may transmit and receive data DATA with a device outside (e.g., external to) the semiconductor device 10. The peripheral circuit 30 may include a row decoder 33, a read/write circuit 35, a control logic 37, and a voltage generator 38 generating various voltages for an operation. According to example embodiments, the peripheral circuit 30 may further include various sub-circuits, such as an input/output circuit, and an error correction circuit for correcting errors in data DATA read from the memory cell array 20.

The control logic 37 may be connected to the row decoder 33, the voltage generator 38, and the input/output circuit. The control logic 37 may control an overall operation of the semiconductor device 10. The control logic 37 may generate various internal control signals used in the semiconductor device 10 in response to the control signal CTRL. For example, the control logic 37 may adjust voltage levels provided to the word lines WL and bit lines BL when performing a memory operation such as a program operation or an erase operation.

The row decoder 33 may select some of a plurality of memory cells in response to an address ADDR and may select at least one word line WL. The row decoder 33 may transmit a voltage for performing a memory operation to the selected word line WL.

The read/write circuit 35 may be connected to the memory cell array 20 through the bit lines BL. The read/write circuit 35 may include a write driver or a sense amplifier. Specifically, during a program operation, the read/write circuit 35 may operate as a write driver to apply a voltage according to data DATA to be stored in the memory cell array 20 to the bit lines BL. In addition, during a read operation, the read/write circuit 35 may operate as a sense amplifier to detect data DATA stored in the memory cell array 20.

The voltage generator 38 may include a controller 52, an oscillator 54, and a charge pump 56.

The charge pump 56 may include a plurality of charge pumps, and each of the plurality of charge pumps may include at least one switching element and at least one pumping capacitor. The charge pump (e.g., charge pump circuit) 56 may provide current through the row decoder 33 to apply an operating voltage to the word line WL of the memory cell array.

The controller 52 may control an operation of the oscillator 54. For example, the controller 52 may determine a selected charge pump among the plurality of charge pumps, based on at least one of the Process, Voltage, Temperature (PVT) information of the semiconductor device 10 and a target level of the power voltage to be supplied. The controller 52 may deactivate the remaining charge pumps except for the selected charge pump.

The oscillator 54 may output a clock signal CLK. The oscillator 54 may operate in response to a control signal VGC from the controller 52. For example, the oscillator 54 may output a clock signal CLK to at least some of the charge pumps, among the plurality of charge pumps, in response to the control signal VGC transmitted by the controller 52.

FIG. 1B is a circuit diagram illustrating a charge pump circuit included in a voltage generator of a semiconductor device according to example embodiments.

Referring to FIG. 1B, a charge pump circuit 56a may include a plurality of diodes DI, a plurality of pumping capacitors CAP1, and an output capacitor CAP2. The plurality of diodes DI may be connected in series with each other, and the plurality of pumping capacitors CAP1 may be connected to a node between the plurality of diodes DI. A first diode may receive a power supply voltage VCC having a predetermined level, and a last diode may output an output current IOUT to an output node.

Each of the plurality of pumping capacitors CAP1 may be charged or discharged by the clock signal CLK or a complementary clock signal CLKB that is phase-shifted to have an opposite phase to the clock signal CLK by an inverter INV. For example, odd-numbered pumping capacitors CAP1 may be charged or discharged by the clock signal CLK, and even-numbered pumping capacitors CAP1 may be charged or discharged by the complementary clock signal CLKB.

FIG. 1C is a schematic perspective view of a semiconductor device according to example embodiments.

Referring to FIG. 1C, the semiconductor device 10 may include a peripheral circuit structure PERI and a memory cell structure CELL. The memory cell structure CELL may be disposed on the peripheral circuit structure PERI. The memory cell structure CELL may be disposed on the peripheral circuit structure PERI. The memory cell structure CELL may be a region in which the memory cell array 20 of FIG. 1A is arranged, and the peripheral circuit structure PERI may be a region in which the peripheral circuit 30 of FIG. 1A is disposed. In some example embodiments, on the contrary, the memory cell structure CELL may be disposed below the peripheral circuit structure PERI.

The memory cell structure CELL may include a first region R1 and a second region R2.

The first region R1 of the memory cell structure CELL may be a region in which the memory cell array 20 is disposed. The second region R2 of the memory cell structure CELL may correspond to a region for electrically connecting memory cells of the memory cell array 20 to the peripheral circuit 30. The second region R2 may be disposed at least in one direction, for example, in an X-direction, at least in one end of the first region R1.

The plurality of pumping capacitors CAP1 included in the charge pump circuits 56 and 56a of FIGS. 1A and 1B may be disposed in the peripheral circuit structure PERI. For example, the plurality of pumping capacitors CAP1 may be disposed below the second region R2 of the memory cell structure CELL in the peripheral circuit structure PERI, but the present invention is not limited thereto. In another example, a plurality of pumping capacitors CAP1 may be disposed below the first region R1 of the memory cell structure CELL in the peripheral circuit structure PERI.

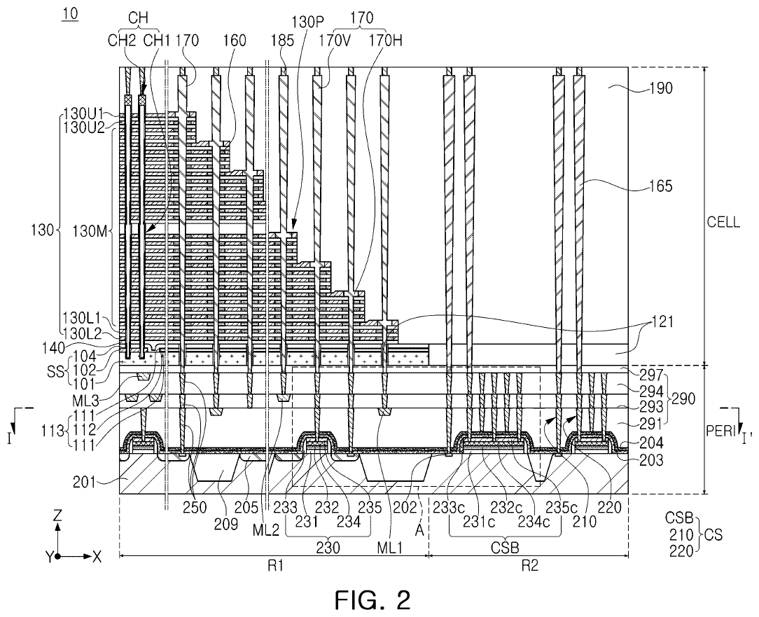

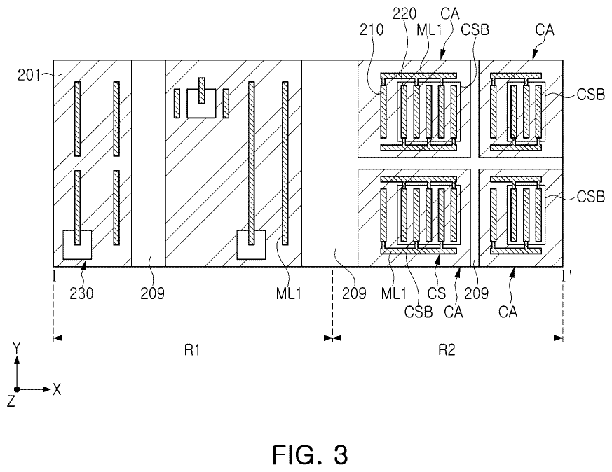

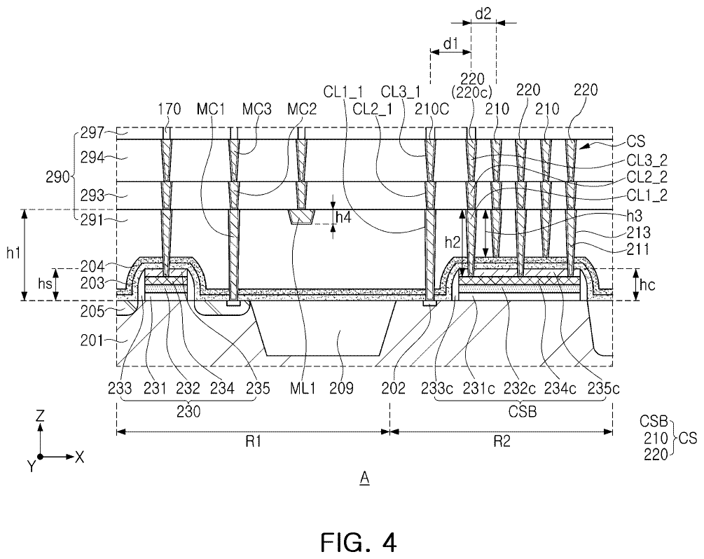

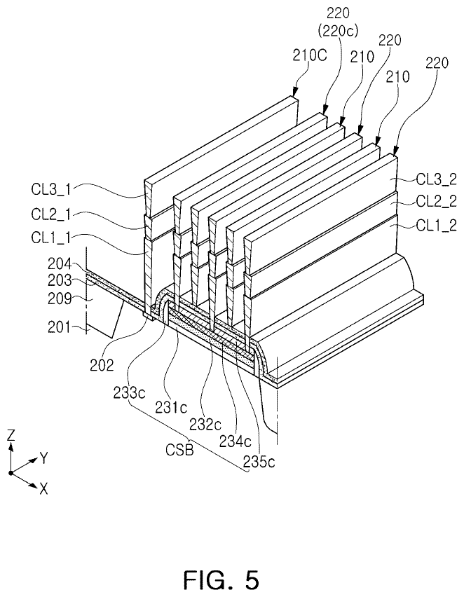

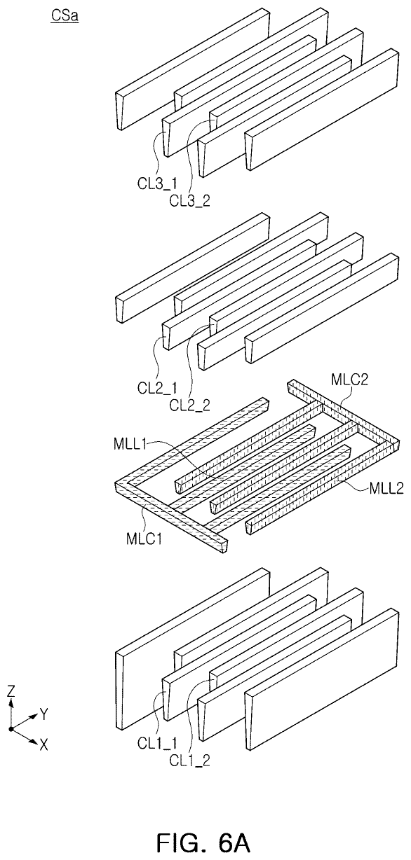

FIG. 2 is a cross-sectional view of a semiconductor device according to example embodiments, FIG. 3 is a plan view of a semiconductor device according to example embodiments, FIG. 4 is an enlarged cross-sectional view of a semiconductor device according to example embodiments, and FIG. 5 is a schematic perspective view illustrating an embodiment of a capacitor structure of a semiconductor device.

Referring to FIGS. 2 to 5, a semiconductor device 10 may include a peripheral circuit structure PERI including a substrate 201 and a memory cell structure CELL including a plate layer 101.

The peripheral circuit structure PERI may include a substrate 201, impurity regions 205 and element isolation regions 209 within the substrate 201, circuit elements 230 disposed on the substrate 201, a peripheral capping insulating layer 290, and an interconnection structure (e.g., interconnection wiring) 250. The peripheral circuit structure PERI may include capacitor structures (e.g., capacitors) CS including a capacitor base structure (e.g., capacitor base) CSB on the substrate 201 and electrode structures (e.g., capacitor electrodes) 210 and 220 on the capacitor base structure CSB.

The substrate 201 may have an upper surface extending in the X-direction and a Y-direction. An active region may be defined by the element isolation regions 209 on the substrate 201. Impurity regions 205 including impurities (charge carrier dopants) may be disposed on a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer. For example, the substrate 201 may be bulk silicon or a silicon-on-insulator (SOI).

The circuit elements 230 may include (e.g., be) planar transistors. Each of the circuit elements 230 may include a gate structure, for example, a peripheral gate dielectric layer 231, a first peripheral gate electrode 232 on the peripheral gate dielectric layer 231, a second peripheral gate electrode 234 disposed on the first peripheral gate electrode 232, a peripheral gate capping layer 235 disposed on the second peripheral gate electrode 234, and a peripheral gate spacer 233 on side surfaces of the peripheral gate dielectric layer 231, the first and second peripheral gate electrodes 232 and 234, the peripheral gate capping layer 235. The impurity regions 205 may be disposed as source/drain regions within the substrate 201 on both sides (e.g., opposite sides) of the first and second peripheral gate electrodes 232 and 234. The circuit elements 230 may have a gate structure as a stack structure having an element height hs from the substrate 201.

A first substrate insulating layer 203 may be disposed along an upper surface of the substrate 201 and the profile of the circuit elements 230. The first substrate insulating layer 203 may include a semiconductor oxide, and may include a silicon oxide, or silicon carbide. A second substrate insulating layer 204 may be disposed on the first substrate insulating layer 203 to conformally cover the first substrate insulating layer 203. The second substrate insulating layer 204 may include a material having etch selectivity with respect to the first substrate insulating layer 203, a material having etch selectivity with respect to a first capping insulating layer 291, and may include a silicon nitride.

The peripheral capping insulating layer 290 may be disposed on the circuit elements 230 on the second substrate insulating layer 204. The peripheral capping insulating layer 290 may include a plurality of insulating layers 291, 293, 294 and 297 formed on different process processes. The plurality of insulating layers 291, 293, 294 and 297 may be formed to have a sufficient thickness and may have a flat upper surface. The peripheral capping insulating layer 290 may be made of an insulating material.

The interconnection structure 250 may include contact plugs MC1, MC2 and MC3 and interconnection lines ML1, ML2 and ML3. However, the present invention is not limited thereto, and the structure of the interconnection structure 250 may be variously changed. The interconnection structure 250 may be electrically connected to the circuit elements 230 and the impurity regions 205. The interconnection structure 250 may be referred to as a lower interconnection structure or a circuit interconnection structure. The contact plugs MC1, MC2 and MC3 may have a pillar shape, and the interconnection lines ML1, ML2 and ML3 may have a line shape. An electrical signal may be applied to the circuit element 230 by the interconnection structure 250. A portion of the first contact plugs MC1 may also be connected to the second peripheral gate electrode 234 and the impurity regions 205. A resistance mitigating layer 202 doped with a high concentration of impurities may be disposed in a contact region between the impurity regions 205 and the first contact plug MC1. The interconnection lines ML1, ML2 and ML3 may be connected to the contact plugs MC1, MC2 and MC3, and may be disposed in the form of a plurality of layers. The contact plugs MC1, MC2 and MC3 and the interconnection lines ML1, ML2 and ML3 may include a conductive material layer 211. For example, the conductive material layer 211 may include tungsten (W), copper (Cu), and aluminum (Al), and the conductive material layer 211 may be surrounded by a diffusion barrier 213. The diffusion barrier 213 may include a metal nitride such as tungsten nitride, titanium nitride, tantalum nitride, or the like, but the present invention is not limited thereto.

The capacitor structures CS may be spaced apart from the peripheral circuit elements 230 and the interconnection structure 250 and disposed within the second region R2 of the peripheral circuit structure PERI. Each of the capacitor structures CS may be arranged within a capacitor region CA physically and electrically separated (e.g., isolated) by an element isolation region 209. An area of the capacitor region CA in which each of the capacitor structures CS is disposed may be different from each other. For example, the capacitor region CA may have different areas depending on capacitances required for respective pumping capacitors CAP of the charge pump circuit 56 illustrated in FIGS. 1A to 1C. The capacitance of the capacitor structure CS may be determined by the area of the capacitor region CA in which the capacitor structure (e.g., pattern) CS is disposed, the area of each of the electrode structures 210 and 220 in a Y-Z plane, and the area and number of the electrode structures 210 and 220. As the area increases, the capacitance is higher, and as the length in a Z-direction and a Y-direction increases, the capacitance is higher, and as the number of electrode structures 210 and 220 increases, the capacitance is higher.

In FIGS. 2 to 5, four capacitor structures CS disposed in each of four capacitor regions CA are illustrated, but the present invention is not limited thereto. Additionally, the capacitor structures CS are illustrated as having four electrode structures 210 and 220 or six electrode structures 210 and 220, but the present invention is not limited thereto. A detailed structure of the capacitor structure CS will be described below.

The memory cell structure CELL may have first and second regions R1 and R2, and may include a source structure SS, gate electrodes 130 stacked on the source structure SS, interlayer insulating layers 140 stacked alternately with the gate electrodes 130, channel structures (e.g., vertical channel structures) CH disposed to penetrate through the stack structure of the gate electrodes 130, and contact plugs 170 connected to the gate electrodes 130 and extending vertically. The memory cell structure CELL may further include a horizontal insulating layer 113 disposed below the gate electrodes 130, substrate insulating layers 121 disposed to penetrate through the plate layer 101, studs 185 on the contact plugs 170, and a cell region insulating layer 190 covering the gate electrodes 130.

In the memory cell structure CELL, the first region R1 may be a region in which gate electrodes 130 are vertically stacked to form memory cells or are connected to contact plugs 170. The second region R2 may be an outer region of the plate layer 101.

The source structure SS may include a plate layer 101, a first horizontal conductive layer 102, and a second horizontal conductive layer 104, which are sequentially stacked. The plate layer 101 has a plate shape and may function as at least a portion of a common source line of the semiconductor device 10. The plate layer 101 may include a conductive material, for example, a semiconductor material. The plate layer 101 may further include impurities. The plate layer 101 may be provided as a polycrystalline semiconductor layer such as a polycrystalline silicon layer or an epitaxial layer.

The first and second horizontal conductive layers 102 and 104 may be sequentially stacked and disposed on an upper surface of the plate layer 101 in a region in which the channel structures CH are disposed. The first horizontal conductive layer 102 may function as a portion of a common source line of the semiconductor device 10, and, for example, may function as a common source line together with the plate layer 101. The first horizontal conductive layer 102 may be directly connected to the channel layer in the channel structure CH. The first and second horizontal conductive layers 102 and 104 may include a semiconductor material, and may include, for example, polycrystalline silicon.

The horizontal insulating layer 113 may be disposed on the plate layer 101 on the same level as that of the first horizontal conductive layer 102. The horizontal insulating layer 113 may include first and second horizontal insulating layers 111 and 112 alternately stacked on the plate layer 101. The horizontal insulating layer 113 may be layers remaining after a portion in a manufacturing process of the semiconductor device 10 is replaced with the first horizontal conductive layer 102. The horizontal insulating layer 113 may include a silicon oxide, a silicon nitride, a silicon carbide, or a silicon oxynitride. The first horizontal insulating layers 111 and the second horizontal insulating layer 112 may include different insulating materials.

The substrate insulating layers 121 may be disposed to penetrate through the plate layer 101, the horizontal insulating layer 113, and the second horizontal conductive layer 104. The substrate insulating layer 121 may include an insulating material, for example, a silicon oxide, a silicon nitride, a silicon carbide, or a silicon oxynitride.

The gate electrodes 130 may be vertically spaced apart from each other and stacked on the plate layer 101 to form a stack structure together with the interlayer insulating layers 140. The stack structure may include vertically stacked lower and upper stack structures. The gate electrodes 130 may include first upper gate electrodes 130U1 and 130U2 included in string select transistors, memory gate electrodes 130M included in a plurality of memory cells, and second lower gate electrodes 130L1 and 130L2 included in a ground select transistor. The number of memory gate electrodes 130M included in memory cells may be determined according to the capacity of the semiconductor device 10.

The gate electrodes 130 may be vertically spaced apart from each other and stacked on the first region R1 to form staircase-shaped step structures by extending by different lengths in the X-direction. By the step structure, the gate electrodes 130 may respectively have contact regions 130P exposed upwardly from the interlayer insulating layers 140 by allowing a lower gate electrode 130 to extend to be longer than an upper gate electrode 130. The gate electrodes 130 may be connected to the contact plugs 170 in the contact regions 130P, which are end regions, respectively.

The gate electrodes 130 may include a metal material, such as tungsten (W). According to an example embodiment, the gate electrodes 130 may include polycrystalline silicon or a metal silicide material. The gate electrodes 130 may include the same material as a whole. In example embodiments, the gate electrodes 130 may further include a diffusion barrier, and for example, the diffusion barrier may include tungsten nitride (WN), tantalum nitride (TaN), titanium nitride (TiN), or combinations thereof.

The interlayer insulating layers 140 may be disposed between the gate electrodes 130. The interlayer insulating layers 140 may also be spaced apart from each other in a direction, perpendicular to the upper surface of the plate layer 101, and may be disposed to extend in the X-direction, similarly to the gate electrodes 130. The interlayer insulating layers 140 may include an insulating material, such as a silicon oxide or a silicon nitride.

The channel structures CH may extend in the Z-direction through the gate electrodes 130, and may be connected to the plate layer 101. The channel structures CH may extend lengthwise in the Z-direction through the gate electrodes 130. An item, layer, or portion of an item or layer described as extending “lengthwise” in a particular direction has a length in the particular direction and a width perpendicular to that direction, where the length is greater than the width. Each of the channel structures CH may form a single memory cell string, and may be spaced apart from each other by forming rows and columns on the plate layer 101. The channel structures CH may be disposed to form a grid pattern in an X-Y plane or may be disposed in a zigzag shape in one direction. The channel structures CH have a pillar shape, and may have an inclined side surface that becomes narrower as channel structures CH get closer to the plate layer 101.

The channel structures CH may include lower and upper channel structures CH1 and CH2 which are vertically stacked. The channel structures CH may have a form in which the lower channel structures CH1 and the upper channel structures CH2 are connected, and may have a bent portion due to a difference in width in a connection region. However, according to example embodiments, the number of channel structures stacked in the third direction (Z-direction) may be variously changed. Each of the channel structures CH may include a channel layer disposed within a channel hole, a gate dielectric layer, a channel buried insulating layer, and a channel pad on an upper end.

The contact plugs 170 may be connected to the contact regions 130P of the gate electrodes 130. The contact plugs 170 may penetrate through at least a portion of the cell region insulating layer 190, and may be connected to each of the contact regions 130P of the gate electrodes 130 exposed upwardly. The contact plugs 170 may penetrate through the gate electrodes 130 below the contact regions 130P, may penetrate through the second horizontal conductive layer 104, the horizontal insulating layer 113 and the plate layer 101, and may be connected to the lower interconnection structure 250 within the peripheral circuit structure PERI.

The contact plugs 170 may be spaced apart from the gate electrodes 130 below the contact regions 130P by contact insulating layers 160. The contact plugs 170 may be spaced apart from the plate layer 101, the horizontal insulating layer 113, and the second horizontal conductive layer 104 by the substrate insulating layers 121.

Each of the contact plugs 170 may have a horizontally expanded shape in the contact region 130P. The contact plug 170 may include a vertical extension portion 170V extending in the Z-direction and a horizontal extension portion 170H extending horizontally from the vertical extension portion 170V and contacting the gate electrode 130. The horizontal extension portion 170H may be disposed along the circumference of the vertical extension portion 170V and an entire side surface of the horizontal extension portion 170H may be surrounded by the gate electrode 130. The contact plugs 170 may be spaced apart from the gate electrodes 130 below the contact regions 130P, e.g., the gate electrodes 130 that are not electrically connected, by the contact insulating layers 160.

The contact plugs 170 may include a conductive material, for example, at least one of tungsten (W), copper (Cu), aluminum (Al), and alloys thereof.

The contact insulating layers 160 may be disposed to surround each side surface of the contact plugs 170 below the contact regions 130P. The contact insulating layers 160 may be spaced apart from each other in the Z-direction around each of the contact plugs 170. The contact insulating layers 160 may be disposed on substantially the same level as the gate electrodes 130, respectively. The contact insulating layers 160 may include an insulating material, and may, for example, be a silicon oxide, a silicon nitride, or a silicon oxynitride.

The studs 185 may form a cell interconnection structure electrically connected to memory cells within the memory cell structure CELL. The studs 185 may be connected to the channel structures CH and the contact plugs 170, and may be electrically connected to the channel structures CH and the gate electrodes 130. The studs 185 may include metal, for example, tungsten (W), copper (Cu), and aluminum (Al).

The cell region insulating layer 190 may be disposed to cover the stack structure of the gate electrodes 130 and the contact plugs 170. The cell region insulating layer 190 may be formed of an insulating material, and may be formed of a plurality of insulating layers.

Capacitor contacts 165 may be disposed in the second region R2 of the memory cell structure CELL, which is an outer region of the plate layer 101, and may penetrate through the cell region insulating layer 190 and may extend to the peripheral circuit structure PERI. The capacitor contacts 165 may be disposed to be connected with the studs 185 of the memory cell structure CELL and the interconnection structure 250 of the peripheral circuit region PERI. The capacitor contacts 165 may include a conductive material, and may include, for example, a metal material such as tungsten (W), copper (Cu), or aluminum (Al). The capacitor contacts 165 may be formed in the same process operation as contact plugs 170, may include the same material, and may have the same internal structure.

The capacitor structures CS may be disposed in the second region R2 and may perform a function of storing charges. Hereinafter, the capacitor structures CS will be described in detail with reference to FIGS. 2 to 5.

FIG. 3 is a plan view taken along line I-I′ of the semiconductor device 10 of FIG. 2, FIG. 4 is an enlarged cross-sectional view of area ‘A’ of FIG. 2, and illustrates one capacitor structure CS, and FIG. 5 is a perspective view of the capacitor structure CS of FIG. 4.

Referring to FIGS. 2 and 3, the capacitor structures CS may be disposed in the capacitor region CA individually separated (e.g., spaced apart) by element isolation regions 209 within the second region R2. As described above, an area of the capacitor region CA occupied by each capacitor structure CS may be different, but the present invention is not limited thereto, and the number of electrode structures 210 and 220 disposed in each capacitor structure CS may also be different.

A shape of the capacitor region CA of each capacitor structure CS may be a square as illustrated in FIG. 3, but the present invention is not limited thereto. Each capacitor region CA may be partitioned by dividing the substrate 201 by the element isolation region 209, so that the capacitor region CA may be electrically and physically isolated.

The element isolation region 209 separating the first region R1 and the second region R2 may extend in the Y-direction to electrically isolate the substrate 201 of the second region R2, and may extend in the X-direction or the Y-direction to divide the capacitor region CA of each capacitor structure CS within the second region R2.

FIG. 3 is a cross-sectional view taken along an upper surface of the first interconnection line ML1, upper surfaces of the first contact plugs MC1, and an upper surface of the first peripheral capping insulating layer 291, in the peripheral circuit structure PERI of the semiconductor device 10 of FIG. 2, and illustrates only the first interconnection line ML1, the first contact plugs MC1, and the elements 230 necessary for the explanation.

Each of the capacitor structures CS may include a capacitor base structure CSB and electrode structures 210 and 220 within an allocated capacitor region CA.

The capacitor base structure CSB may occupy most of an area of the capacitor region CA and may include a separation space in an edge region on one side thereof.

The separation space may be defined as a region in which the substrate 201 is exposed between the element isolation region 209 and the capacitor base structure CSB.

The capacitor base structure CSB is a stack structure disposed on the substrate 201, and may have the same layer structure as the gate structure of the peripheral circuit element 230 and may be a stack structure having a base height hc that is the same as the element height hs from the substrate 201.

The capacitor base structure CSB may include a dielectric layer 231c, a first base conductive layer 232c on the dielectric layer 231c, a second base conductive layer 234c disposed on the first base conductive layer 232c, a base capping layer 235c disposed on the second base conductive layer 234c, and a base spacer 233c on side surfaces of the dielectric layer 231c, the first and second base conductive layers 232c and 234c and the base capping layer 235c.

The capacitor base structure CSB may be disposed in a polygonal shape, for example, a square shape, within each capacitor region CA, and may be formed by sequentially stacking the dielectric layer 231c, the first and second base conductive layers 232c and 234c, and the base capping layer 235c in the Z-direction.

The dielectric layer 231c may include the same material as the peripheral gate dielectric layer 231 of the peripheral circuit element 230, and the material of dielectric layer 231c may be at least one of a silicon oxide film, a silicon nitride film, or a silicon oxynitride film, but the present invention is not limited thereto. The dielectric layer 231c may include the same thickness as the peripheral gate dielectric layer 231.

The first base conductive layer 232c may include the same material as the first peripheral gate electrode 232 of the peripheral circuit element 230, and may have the same thickness. The first base conductive layer 232c may include a semiconductor material, and may include polysilicon, doped polysilicon, or GaAs, but the present invention is not limited thereto.

The second base conductive layer 234c may include the same material as the second peripheral gate electrode 234 of the peripheral circuit element 230, and may have the same thickness. The second base conductive layer 234c may include a metal material, and may include tungsten, but the present invention is not limited thereto.

The base capping layer 235c may include the same material as the peripheral gate capping layer 235 of the peripheral circuit element 230, and may have the same thickness. The base capping layer 235c may include a silicon nitride film, but the present invention is not limited thereto.

The base spacer 233c may include the same material as the peripheral gate spacer 233 of the peripheral circuit element 230. The second base conductive layer 234c may include the same material as the second peripheral gate electrode 234 of the peripheral circuit element 230.

The first substrate insulating layer 203 and the second substrate insulating layer 204 may be conformally stacked and disposed on the capacitor base structure CSB as described above. Accordingly, the first substrate insulating layer 203 and the second substrate insulating layer 204 may be understood as being disposed to cover the first region R1 and the second region R2 as a whole.

The capacitor structure CS may include a plurality of first electrode structures 210 and a plurality of second electrode structures 220 within the capacitor region CA. The first electrode structures 210 and the second electrode structures 220 may have a plate shape in a Z-Y plane and may be disposed alternately in the X-direction. Upper ends of the first electrode structures 210 and the second electrode structures 220 in the Z-direction may be disposed on substantially the same level. In one example, the capacitor structure CS may further include an insulating layer (e.g., the peripheral capping insulating layer 290 of FIG. 2) filling a space between the first electrode structure 210 and the second electrode structure 220.

The first electrode structure 210 and the second electrode structure 220 may have different potentials. In one example, the first electrode structure 210 and the second electrode structure 220 may receive an electrical signal through a separate interconnection line connected to each of the first electrode structure 210 and the second electrode structure 220.

A plurality of subsidiary capacitor electrodes CL1_1, CL1_2, CL2_1, CL2_2 CL3_1 and CL3_2 having the form of plates may be stacked on each of the first electrode structure 210 and the second electrode structure 220.

Each of the first electrode structures 210 may include the first lower subsidiary capacitor electrode CL1_1, a first intermediate subsidiary capacitor electrode CL2_1, and a first upper subsidiary capacitor electrode CL3_1, which are sequentially stacked in the Z-direction.

At least one of the first electrode structures 210 may have a length h1 of the first lower subsidiary capacitor electrode CL1_1 different from a length of a first lower subsidiary capacitor electrode CL1_1 of the other first electrode structures 210. For example, the length h1 of the first lower subsidiary capacitor electrode CL1_1 of at least one of the first electrode structures 210 may be longer than the length of the first lower subsidiary capacitor electrode CL1_1 of the other first electrode structures 210.

Specifically, the first electrode structure disposed on one side of the first electrode structures 210 may be defined as a first contact electrode structure (e.g., contact electrode) 210C, the first contact electrode structure 210C may be disposed in a separation space, may be spaced apart from the capacitor base structure CSB, and may extend in the Z-direction so that a lower end of the first lower subsidiary capacitor electrode CL1_1 is in contact with the upper surface of the substrate 201.

Other first electrode structures 210 except for the first contact electrode structure 210C, among the first electrode structures 210, may be disposed on the capacitor base structure CSB, and the lower ends of the first lower subsidiary capacitor electrodes CL1_1 are disposed on the same level, and the lower ends of the first lower subsidiary capacitor electrodes CL1_1 may be disposed on the same level as or lower than an upper surface of the second substrate insulating layer 204, but may be disposed on a higher level than the upper surface of the first substrate insulating layer 203.

Positions of the lower ends of the first lower subsidiary capacitor electrodes CL1_1 of the first electrode structures 210 may be different, but upper ends thereof may be substantially the same, and may be substantially the same as those of upper ends of the first interconnection lines ML1 of the interconnection structure 250 and the first contact plugs MC1. For example, the upper ends of the first lower subsidiary capacitor electrodes CL1_1 of the first electrode structures 210 may form a coplanar surface with the upper surface of the first peripheral capping insulating layer 291.

Accordingly, the first lower subsidiary capacitor electrode CL1_1 of the first contact electrode structure 210C, among the first electrode structures 210, may have a first length h1 in the Z-direction, and the first lower subsidiary capacitor electrodes CL1_1 of the other first electrode structures 210 may have a third length h3 in the Z-direction, and the third length h3 may be less than the first length h1 and equal to or greater than a fourth length h4 of the first interconnection lines ML1 in the Z-direction.

The first lower subsidiary capacitor electrode CL1_1 of the first contact electrode structure 210C may have a first length h1 substantially the same as that of some of the first contact plugs MC1, for example, the first contact plugs MC1 in contact with the impurity region 205 which is a source/drain region, but the present invention is not limited thereto.

The subsidiary capacitor electrodes CL2_1 and CL3_1 stacked on the first lower subsidiary capacitor electrode CL1_1 may have a relatively larger height toward an upper portion. For example, the upper subsidiary capacitor electrode CL3_1 may have a greater length in the Z-direction than that of the intermediate subsidiary capacitor electrode CL2_1. However, the lower subsidiary capacitor electrode CL1_1 may be formed on the same level as the contact plugs MC1 in contact with the circuit elements 230 of the substrate 201, and thus may have a greater length h1 than the intermediate subsidiary capacitor electrode CL2_1 in the upper portion.

Upper ends of the first intermediate subsidiary capacitor electrodes CL2_1 of the first electrode structures 210 may be disposed on the same level as each other, and lower ends thereof may be disposed on the same level as each other, and thus, the first intermediate subsidiary capacitor electrodes CL2_1 may have the same length in the Z-direction, and the length thereof may be substantially the same as a thickness of the second peripheral capping insulating layer 293.

Upper ends of the first upper subsidiary capacitor electrodes CL3_1 of the first electrode structures 210 may be disposed on the same level as each other, and lower ends thereof may be disposed on the same level as each other, and thus, the first upper subsidiary capacitor electrodes CL3_1 may have the same length in the Z-direction, and the length thereof may be substantially the same as a thickness of the third peripheral capping insulating layer 294.

Each of the first electrode structures 210 may have a stack structure of the first lower subsidiary capacitor electrode CL1_1, the first intermediate subsidiary capacitor electrode CL2_1, and the first upper subsidiary capacitor electrode CL3_1 aligned in (e.g., extending along) the Z-direction, and may have a wall shape penetrating through the first to third peripheral capping insulating layers 291, 293 and 294, thereby functioning as an integrated subsidiary capacitor electrode. For example, a width in the X-direction may be much less than a length in the Y-direction, and may extend in the Z-direction to form a plate shape on the Y-Z plane. Each of the first electrode structures 210 may have two side surfaces extending in the Y-direction between an upper end and a lower end and opposing each other, and two side surfaces extending in the X-direction and opposing each other, and the two side surfaces in the Y-direction may occupy most of an area of the capacitor structure CS.

Each of the first lower, intermediate, and upper subsidiary capacitor electrodes CL1_1, CL2_1 and CL3_1 may be configured so that a width of an upper end in the X-direction is greater than a width of a lower end, the width decreases toward a lower end, and a side surface may have an inclination. Boundaries of the first lower, intermediate, and upper subsidiary capacitor electrodes CL1_1, CL2_1 and CL3_1, e.g., a region in which a lower end of the upper portion and an upper end of the lower portion are in contact with each other, may have a bent portion.

In this case, a width of an upper end of the first upper subsidiary capacitor electrode CL3_1 may be greater than a width of an upper end of the first lower subsidiary capacitor electrode CL1_1, and thus, a space between a lower end of the first upper subsidiary capacitor electrode CL3_1 and an upper end of the first intermediate subsidiary capacitor electrode CL2_1 may extend without a bent portion, and a direction of the bent portion may be opposite, but the present invention is not limited thereto.

The second electrode structures 220 may be disposed alternately with the first electrode structures 210 in the X-direction, and may be disposed on the capacitor base structure CSB. Accordingly, the second electrode structures 220 may be disposed to overlap the capacitor base structure CSB in the Z-direction. Lower ends of the second electrode structures 220 may be disposed to penetrate partially through the capacitor base structure CSB.

Each of the second electrode structures 220 may include a second lower subsidiary capacitor electrode CL1_2, a second intermediate subsidiary capacitor electrode CL2_2, and a second upper subsidiary capacitor electrode CL3_2 which are sequentially stacked in the Z-direction. Unlike the first electrode structures 210, the second electrode structures 220 may all have the same length in the Z-direction. For example, the upper ends of each of the second lower subsidiary capacitor electrodes CL1_2 may be disposed on the same level as each other, and the lower ends of the second lower subsidiary capacitor electrodes CL1_2 may be disposed on the same level as each other.

In this case, the second lower subsidiary capacitor electrodes CL1_2 may be longer than the first lower subsidiary capacitor electrode CL1_1 on the capacitor base structure CSB. Specifically, a lower end of the second lower subsidiary capacitor electrode CL1_2 of the second electrode structures 220 may be disposed on a level equal to or lower than an upper surface of the second base conductive layer 234c, but may be disposed on a level higher than an upper surface of the first base conductive layer 232c. The lower end of the second lower subsidiary capacitor electrode CL1_2 may be disposed on the same level as a lower end of the first contact plug MC1 disposed on the gate structure of the peripheral circuit element 230.

Positions of the upper ends of the second lower subsidiary capacitor electrodes CL1_2 of the second electrode structures 220 may be substantially the same as those of the upper ends of the first interconnection lines ML1 of the interconnection structure 250. For example, the upper ends of the second lower subsidiary capacitor electrodes CL1_2 may be coplanar with the upper surface of the first peripheral capping insulating layer 291, and may be substantially the same as the upper ends of the first lower subsidiary capacitor electrodes CL1_1.

Accordingly, the second lower subsidiary capacitor electrode CL1_2 of the second electrode structures 220 may have a second length h2 in the Z-direction, and the second length h2 may be less than the first length h1 and greater than the third length h3.

In this manner, the first electrode structures 210 and the second electrode structures 220 may be alternately disposed in the X-direction on the capacitor base structure CSB, and may be connected to the capacitor base structure CSB with different lengths.

The subsidiary capacitor electrodes CL2_2 and CL3_2 stacked on the second lower subsidiary capacitor electrode CL1_2 may have a relatively larger height toward an upper portion.

For example, the second upper subsidiary capacitor electrode CL3_2 may have a greater length in the Z-direction than the second intermediate subsidiary capacitor electrode CL2_2. However, the second lower subsidiary capacitor electrode CL1_2 may be formed on the same level as the first contact plug MC1 in contact with the circuit elements 230 of the substrate 201, and may thus have a greater length than the second intermediate subsidiary capacitor electrode CL2_2 in an upper portion thereof.

The second intermediate subsidiary capacitor electrodes CL2_2 of the second electrode structures 220 may be disposed in the same position as that of the first intermediate subsidiary capacitor electrodes CL2_1, and upper ends thereof may be disposed on the same level as each other, and lower ends thereof may be disposed on the same level as each other, so that the second intermediate subsidiary capacitor electrodes CL2_2 may have the same length in the Z-direction, and the length thereof may be substantially the same as the thickness of the second peripheral capping insulating layer 293.

The second upper subsidiary capacitor electrode CL3_2 of the second electrode structures 220 may be disposed in the same position as that of the first upper subsidiary capacitor electrode CL3_1, and upper ends thereof may be disposed on the same level as each other, and lower ends thereof may be disposed on the same level as each other, so that the second upper subsidiary capacitor electrode CL3_2 may have the same length in the Z-direction, and the length thereof may be substantially the same as the thickness of the third peripheral capping insulating layer 294.

Each of the second electrode structures 220 has a stack structure of the second lower subsidiary capacitor electrode CL1_2, the second intermediate subsidiary capacitor electrode CL2_2, and the second upper subsidiary capacitor electrode CL3_2 aligned in the Z-direction, and may have a wall shape penetrating through the first to third peripheral capping insulating layers 291, 293 and 294, thereby functioning as an integrated subsidiary capacitor electrode.

Each of the second electrode structures 220 may have two side surfaces extending in the Y-direction between an upper end and a lower end and opposing each other, and two side surfaces extending in the X-direction and opposing each other, and the two side surfaces in the Y-direction may occupy an area of the main electrode of the capacitor structure CS.

Each of the second lower, intermediate, and upper subsidiary capacitor electrodes CL1_2, CL2_2 and CL3_2 may be configured so that a width of an upper end in the X-direction is greater than a width of a lower end, the width may decrease toward a lower end, and a side surface may have an inclination. Boundaries of the second lower, intermediate, and upper subsidiary capacitor electrodes CL1_2, CL2_2 and CL3_2, e.g., a region in which a lower end of the upper portion and an upper end of the lower portion are in contact with each other, may have a bent portion. In this case, a width of the upper end of the second upper subsidiary capacitor electrode CL3_2 may be substantially the same as a width of the upper end of the first upper subsidiary capacitor electrode CL3_1, and may have a width greater than that of an upper end of the second lower subsidiary capacitor electrode CL1_2, and thus, a space between the lower end of the second upper subsidiary capacitor electrode CL3_2 and the upper end of the second intermediate subsidiary capacitor electrode CL2_2 may extend without a bent portion, and a direction of the bent portion may be opposite, but the present invention is not limited thereto.

Each of the first and second lower subsidiary capacitor electrodes CL1_1 and CL1_2, the first and second intermediate subsidiary capacitor electrodes CL2_1 and CL2_2, and the first and second upper subsidiary capacitor electrodes CL3_1 and CL3_2 may be formed by a dual damascene process. For example, during the dual damascene process of forming the first contact plug MC1 and the first interconnection line ML1, the first and second lower subsidiary capacitor electrodes CL1_1 and CL1_2 may be formed, during the dual damascene process of forming the second contact plug MC2 and the second interconnection line ML2, the first and second intermediate subsidiary capacitor electrodes CL2_1 and CL2_2 may be formed, and during the dual damascene process of forming the third contact plug MC3 and the third interconnection line ML3, the first and second upper subsidiary capacitor electrodes CL3_1 and CL3_2 may be formed.

The first electrode structure 210 and the second electrode structure 220 may include a conductive material layer 211. For example, the conductive material layer 211 may include a metal such as tungsten (W), titanium (Ti), tantalum (Ta), copper (Cu), and aluminum (Al), but the present invention is not limited thereto. The first electrode structure 210 and the second electrode structure 220 may include a diffusion barrier 213 between the conductive material layer 211 and the respective capping insulating layers 290. The diffusion barrier 213 may include a metal nitride such as WN, TiN, and TaN, but the present invention is not limited thereto. The diffusion barrier 213 may not be disposed on the upper surface between each subsidiary capacitor electrode CL1_1, CL2_1, CL3_1, CL1_2, CL2_2 and CL3_2.

Each of the first electrode structures 210 and the second electrode structures 220 is illustrated as including three subsidiary capacitor electrodes CL1_1, CL2_1, CL3_1, CL1_2, CL2_2 and CL3_2, but the present invention is not limited thereto, and the number of subsidiary capacitor electrodes CL1_1, CL2_1, CL3_1, CL1_2, CL2_2 and CL3_2 included in the first electrode structure 210 and the second electrode structure 220 may be variously changed. One of the first electrode structures 210 and the second electrode structures 220 may be spaced apart from the capacitor base structure CSB and has a lower end in contact with the substrate 201, and the other first electrode structures 210 and the second electrode structures 220 may be disposed to overlap the capacitor base structure CSB in the Z-direction. The first electrode structures 210 and the second electrode structures 220 may be disposed so that wall-shaped surfaces thereof overlap each other in the X-direction, and may have substantially the same length in the Y-direction. Additionally, when the first electrode structures 210 and the second electrode structures 220 are spaced apart in the X-direction, a separation distance may be substantially the same as the second separation distance d2. The first contact electrode structure 210C may be spaced apart from the adjacent second electrode structure 220 by a first separation distance d1, and other first electrode structures 210 and second electrode structures 220 may be spaced apart by a second separation distance d2. The second separation distance d2 may be less than the first separation distance d1.

A semiconductor device 10 according to example embodiments may include a capacitor structure CS, and the capacitor structure CS may include a first electrode structure 210 including a first lower subsidiary capacitor electrode CL1_1 having a relatively greater height in a vertical direction and a second electrode structure 220 including a second lower subsidiary capacitor electrode CL1_2 having a relatively greater height in the vertical direction.

For example, the first electrode structures 210, disposed on the capacitor base structure CSB, may extend to the upper surface of the second substrate insulating layer 204 using the second substrate insulating layer 204 as an etch-stop layer, and the second electrode structures 220 may extend to the second base conductive layer 234c of the capacitor base structure CSB, so that capacitance including the dielectric layer 231c as a capacitor dielectric layer may be secured between the substrate 201 and the first and second base conductive layers 232c and 234c, and capacitance including the first substrate insulating layer 203 as a capacitor dielectric layer may also be secured between the second base conductive layer 234c and the first electrode structures 210. Additionally, the capacitance between the first and second lower subsidiary capacitor electrodes CL1_1 and CL1_2 of the first and second electrode structures 210 and 220 using the first peripheral capping insulating layer 291 as a capacitor dielectric layer may also be secured, so that the capacitance of the first and second electrode structures 210 and 220 may be maximally secured within the first peripheral capping insulating layer 291 having a large thickness, thereby improving the electrical characteristics.

Referring to FIG. 5, for example, a set of the first capacitor electrodes 210 and the second capacitor electrodes 220 may penetrate through at least a portion of the lowermost capping insulating layer (not shown and corresponding to the first peripheral capping insulating layer 291 in FIG. 4) and extend in in the Z-direction. Each capacitor electrode of the set of the first capacitor electrodes may have first and second sidewalls facing away from each other. Each of the second capacitor electrodes has third and fourth sidewalls facing away from each other. In the X-direction, at least one of the first and second sidewalls of each capacitor electrode of the set of the first capacitor electrodes may face at least one of the third and fourth sidewalls of each of the second capacitor electrodes.

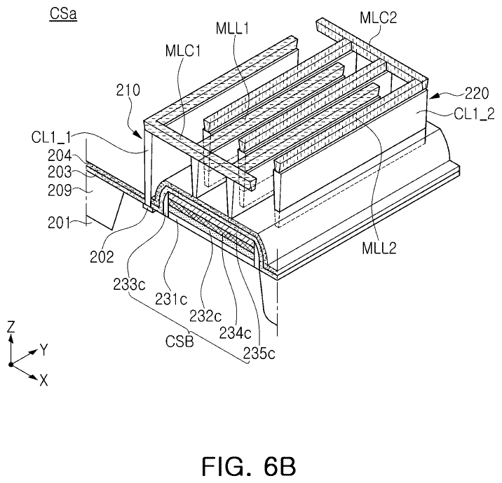

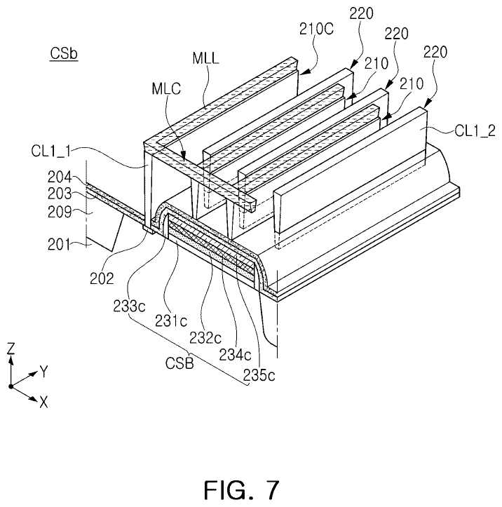

Hereinafter, various example embodiments of the present disclosure will be described with reference to FIGS. 6A to 7. FIG. 6A is an exploded perspective view illustrating the arrangement of first and second subsidiary capacitor electrodes among capacitor structures CS, and FIG. 6B is a perspective view illustrating a capacitor structure CS in which the first and second subsidiary capacitor electrodes of FIG. 6A are coupled.

Referring to FIGS. 6A and 6B, a capacitor structure CSa is the same as the capacitor structure CS of FIGS. 2 to 5, except that the first electrode structure 210 protrudes with respect to the second electrode structure 220.

The capacitor structure CSa may include the first electrode structures 210 and the second electrode structures 220. In one example, the first lower, intermediate, and upper subsidiary capacitor electrodes CL1_1, CL2_1 and CL3_1 included in the first electrode structure 210 may be disposed in the X-direction alternately with the second lower, intermediate, and upper subsidiary capacitor electrodes CL1_2, CL2_2 and CL3_2 included in the second electrode structure 220.

The first electrode structures 210 may protrude and extend in the Y-direction with respect to the second electrode structures 220. In this case, the first electrode structure 210 may further include a first connection portion MLC1 extending in the X-direction and first lower capacitor interconnection lines MLL1 protruding and extending from the first connection portion MLC1 in the Y-direction. The first connection portion MLC1 may electrically connect the first lower capacitor interconnection lines MLL1. In one example, a length of the first connection portion MLC1 in the Z-direction may be substantially equal to the fourth length h4 of the first interconnection line ML1 in the Z-direction.

A height of the first lower subsidiary capacitor electrode CL1_1 in the Z-direction may be less than a height of the first lower subsidiary capacitor electrode CL1_1 of FIGS. 2 to 5.

The second electrode structure 220b may include a second connection portion MLC2 extending the second lower subsidiary capacitor electrode CL1_2 in the X-direction and second lower capacitor interconnection lines MLL2 protruding and extending from the second connection portion MLC2 in the Y-direction. The second connection portion MLC2 may electrically connect the second lower capacitor interconnection lines MLL2. In one example, a height of the second connection portion MLC2 in the Z-direction may be the same as the fourth length h4 of the first interconnection line ML1 in the Z-direction. A height of the second lower subsidiary capacitor electrode CL1_2 in the Z-direction may be less than a height of the second lower subsidiary capacitor electrode CL1_2 of FIGS. 2 to 5.

The first connection portion MLC1 and the second connection portion MLC2 may be spaced apart from each other in the Y-direction, the first lower capacitor interconnection lines MLL1 may be electrically and physically spaced apart from the second connection portion MLC2, and the second lower capacitor interconnection lines MLL2 may be electrically and physically spaced apart from the first connection portion MLC1.

The first and second lower subsidiary capacitor electrodes CL1_1 and CL1_2 and the first and second lower capacitor interconnection lines MLL1 and MLL2 may be formed by a single damascene process, respectively. The first electrode structures 210 and the second electrode structures 220 are disposed so that at least some thereof are misaligned with each other in the Y-direction, so that interconnection connection is possible on the same layer without a separate additional interconnection line.

A zigzag arrangement of the first electrode structures 210 and the second electrode structures 220 may be performed on the capacitor base structure CSB as illustrated in FIG. 6B, and in this case, lower ends thereof may be disposed on different levels so as to contact different layers of the capacitor base structure CSB as in FIGS. 2 to 5.

FIG. 7 is a schematic perspective view illustrating another example embodiment of a capacitor structure of a semiconductor device.

Referring to FIG. 7, the capacitor structure CSb may be the same as the capacitor structure CS of FIGS. 2 to 5, except that the capacitor interconnection lines MLL1 are formed only on the first electrode structure 210.

Referring to FIG. 7, the capacitor structure CSb may be disposed so that the first lower capacitor interconnection lines MLL of the first electrode structure 210 extend in the Y-direction on the first lower subsidiary capacitor electrodes CL1_1, and the connection portion MLC connecting one end of the first lower capacitor interconnection lines MLL may extend in the X-direction.

Through the first lower capacitor interconnection lines MLL and the connection portion MLC, a plurality of first electrode structures 210 may function as one subsidiary capacitor electrode receiving the same voltage, and since all second electrode structures 220 are in contact with the second base conductive layer 234c of the capacitor base structure CSB at the same time, the second electrode structures 220 may be electrically connected to each other through the second base conductive layer 234c and may function as a single subsidiary capacitor electrode. Accordingly, electrical connection may be made without separate second lower capacitor interconnection lines and a separate second connection portion.

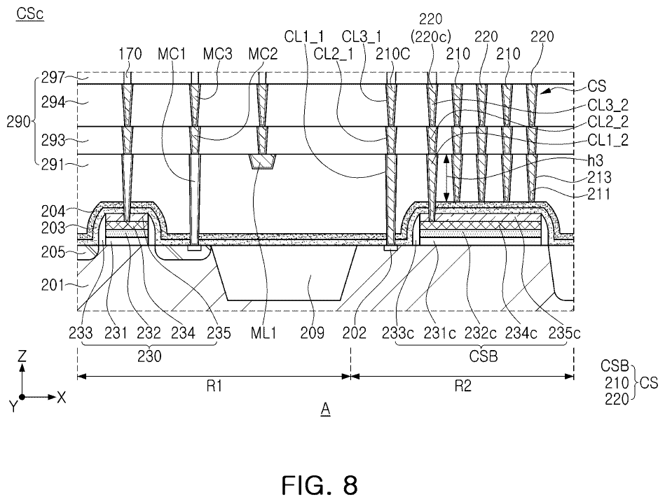

FIGS. 8 to 10 are enlarged cross-sectional views illustrating capacitor structures according to example embodiments. The enlarged cross-sectional views of FIGS. 8 to 10 illustrate portion ‘A’ of FIG. 2.

A capacitor structure CSc of FIG. 8 is the same as the capacitor structure CS of FIGS. 2 to 5, except for positions of lower ends of the first and second electrode structures 210 and 220.

The capacitor structure CSc of FIG. 8 includes first electrode structures 210 and second electrode structures 220 alternating with the first electrode structures 210 in the X-direction. A first electrode structure on one side of the first electrode structures 210 may be defined as a first contact electrode structure 210C, and a second electrode structure on one side of the second electrode structures 220 may be defined as a second contact electrode structure 220C.

The first contact electrode structure 210C may be disposed in a separation space outside the capacitor base structure CSB like the first contact electrode structure 210C of FIGS. 2 to 5. For example, the first contact electrode structure 210C may be spaced apart from the capacitor base structure CSB by a separation space, and the first contact electrode structure 210C may be spaced apart from the second electrode structure 220 of FIGS. 2 to 5 by a separation space. The first lower subsidiary capacitor electrode CL1_1 may extend by a first length h1 so that a lower end thereof is in contact with the upper surface of the substrate 201.

The second contact electrode structure 220C may extend so that a lower end thereof is in contact with the second base conductive layer 234c on the capacitor base structure CSB.

In this case, lower ends of the remaining first electrode structures 210 and second electrode structures 220 may be disposed on substantially the same level. For example, the remaining first electrode structures 210 and second electrode structures 220 on the capacitor base structure CSB may be disposed on the second substrate insulating layer 204 and formed by etching the second substrate insulating layer 204 using an etching stopper.

Accordingly, all of the first and second electrode structures 210 and 220 except for the contact electrode structures for electrical connection may be formed to have the same length and the same area.

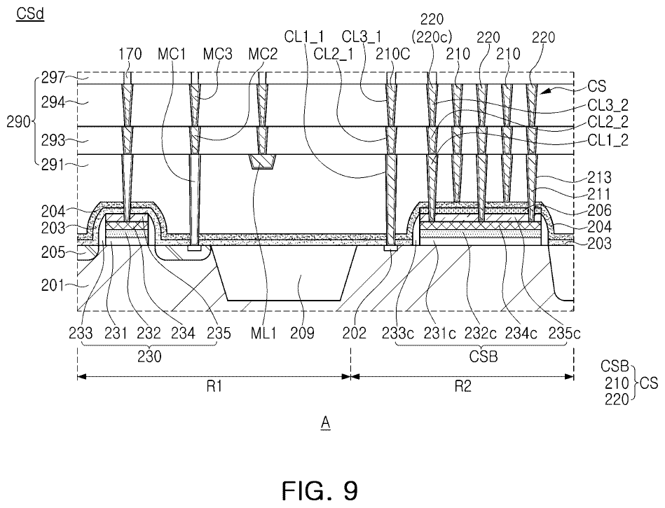

A capacitor structure CSd of FIG. 9 is the same as the capacitor structure CS of FIGS. 2 to 5, except for the capacitor base structure CSB.

The capacitor structure CSd of FIG. 9 may be disposed such that the first substrate insulating layer 203 does not cover the capacitor base structure CSB and is exposed. The second substrate insulating layer 204 may be disposed on the first substrate insulating layer 203 in a region other than the capacitor base structure CSB, and the second substrate insulating layer 204 may be disposed on the capacitor base structure CSB without the first substrate insulating layer 203. In this case, a capacitor dielectric layer 206 may be additionally disposed on an upper surface of the capacitor base structure CSB, For example, between the base capping layer 235c and the second substrate insulating layer 204.

The capacitor dielectric layer 206 may include a high-κ material, such as lanthanum oxide or hafnium oxide, rather than silicon oxides such as a silicon oxide film, silicon nitride film, or silicon carbide film, which are mainly applied as the first substrate insulating layer 203, in order to maximize the capacitance using the capacitor base structure CSB.

For example, the capacitor dielectric layer 206 may include a different material from the first substrate insulating layer 203, and may include a different material from the second substrate insulating layer 204, thereby including a material having etching selectivity with respect to the second substrate insulating layer 204. The capacitor dielectric layer 206 may have a smaller thickness than the second substrate insulating layer 204, and thus may secure a higher capacitance. In the capacitor structure CSd of FIG. 9, the second substrate insulating layer 204 and the capacitor dielectric layer 206 may be disposed without the first substrate insulating layer 203.

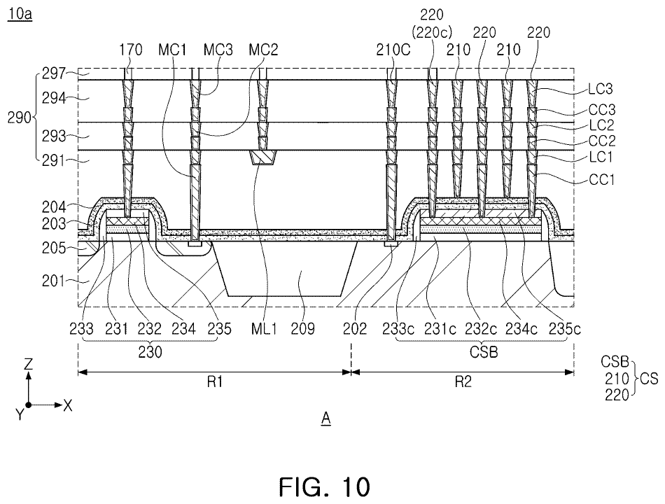

In addition, a capacitor structure CS of a semiconductor device 10a of FIG. 10 is the same as described above in that the capacitor structure CS includes first electrode structures 210 and second electrode structures 220, and the first electrode structures 210 and the second electrode structures 220 are disposed alternately in the X-direction in a wall shape.

In each of the first and second electrode structures 210 and 220, a first lower contact electrode CC1, a first lower interconnection electrode LC1, a first intermediate contact electrode CC2, a first intermediate interconnection electrode LC2, a first upper contact electrode CC3, and a first upper interconnection electrode LC3 may be consecutively disposed in the Z-direction to form a wall shape.

The first lower contact electrode CC1 and the first lower interconnection electrode LC1 may be disposed to penetrate through the first peripheral capping insulating layer 291, the first intermediate contact electrode CC2 and the first intermediate interconnection electrode LC2 may be disposed to penetrate through the second peripheral capping insulating layer 293, and the first upper contact electrode CC3 and the first upper interconnection electrode LC3 may be disposed to penetrate through the third peripheral capping insulating layer 294.

Each of the first lower contact electrode CC1, the first lower interconnection electrode LC1, the first intermediate contact electrode CC2, the first intermediate interconnection electrode LC2, the first upper contact electrode CC3, and the first upper interconnection electrode LC3 may be configured so that a width thereof decreases from an upper end to a lower end and may have an inclined side surface, and a bent portion may be included between the first lower contact electrode CC1, the first lower interconnection electrode LC1, the first intermediate contact electrode CC2, the first intermediate interconnection electrode LC2, the first upper contact electrode CC3, and the first upper interconnection electrode LC3.

Each of the first lower contact electrode CC1, the first lower interconnection electrode LC1, the first intermediate contact electrode CC2, the first intermediate interconnection electrode LC2, the first upper contact electrode CC3 and the first upper interconnection electrode LC3 may be formed through a single damascene process, so that a diffusion barrier 213 may be disposed in a boundary between the first lower contact electrode CC1, the first lower interconnection electrode LC1, the first intermediate contact electrode CC2, the first intermediate interconnection electrode LC2, the first upper contact electrode CC3, and the first upper interconnection electrode LC3. For example, the diffusion barrier 213 may be disposed to surround a bottom surface of an interconnection electrode at an interface between the interconnection electrode and the contact electrode, but the present invention is not limited thereto.

A length of the interconnection electrodes LC1, LC2 and LC3 in the Z-direction may gradually increase as an upper portion, and uppermost interconnection electrodes LC3 may have the greatest width and length.

Each of the first electrode structure 210 and the second electrode structure 220 is illustrated as including three contact electrodes CC1, CC2 and CC3 and three interconnection electrodes LC1, LC2 and LC3, but the present invention is not limited thereto, and the number of contact electrodes CC1, CC2 and CC3 and interconnection electrodes LC1, LC2 and LC3 included in the first electrode structure 210 and the second electrode structure 220 may be variously changed.

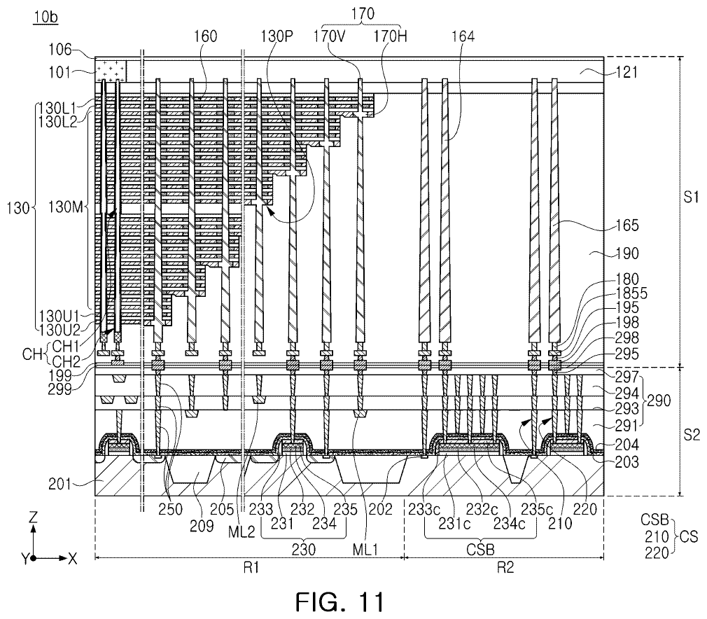

FIG. 11 is a cross-sectional view of a semiconductor device according to example embodiments,

Referring to FIG. 11, a semiconductor device 10b may include a first semiconductor structure (e.g., memory cell structure) S1 and a second semiconductor structure (e.g., peripheral circuit structure) S2 bonded by a wafer bonding method.

The description of the peripheral circuit structure PERI described above with reference to FIG. 2 may be applied to the second semiconductor structure S2. However, the second semiconductor structure S2 may further include second bonding vias 295, second bonding metal layers 298, and a second bonding insulating layer 299, which are bonding structures. The second bonding vias 295 may be connected to the uppermost interconnection lines ML1, ML2 and ML3. At least a portion of the second bonding metal layer 298 may be connected to the second bonding vias 295. The second bonding metal layer 298 may be connected to first bonding metal layers 198 of the first semiconductor structure S1. The second bonding metal layers 298 may provide an electrical connection path according to the bonding of the first semiconductor structure S1 and the second semiconductor structure S2 together with the first bonding metal layers 198. Some of the second bonding metal layers 298 may not be connected to the lower interconnection lines ML1, ML2 and ML3, and may be disposed only for bonding.

The second bonding vias 295 and the second bonding metal layers 298 may include a conductive material, and may include, for example, copper (Cu). The second bonding insulating layer 299 may be disposed around the second bonding metal layers 298. The second bonding insulating layer 299 may also function as a diffusion barrier layer of the second bonding metal layers 298, and may include, for example, at least one of SiN, SiON, SiCN, SiOC, SiOCN, or SiO.

Unless otherwise described, the description of the memory cell structure CELL described above with reference to FIGS. 2 to 5 may be applied to the first semiconductor structure S1. The first semiconductor structure S1 may further include studs 180 and cell interconnection lines 1855. The first semiconductor structure S1 may further include first bonding vias 195, first bonding metal layers 198, and a first bonding insulating layer 199, which are included in a bonding structure. In one example, the first semiconductor structure S1 may further include a passivation layer 106 covering an upper surface of the plate layer 101 and an upper surface of the substrate insulating layers 121.

The studs 180 may form a cell interconnection structure electrically connected to the memory cells of the first semiconductor structure S1. The studs 180 may be connected to the channel structures CH and the contact plugs 170 and may be electrically connected to the channel structures CH and the gate electrodes 130. The studs 180 are illustrated in a plug shape, but the present invention is not limited to and may have a line shape. In one example, the studs 180 may include a metal, and may include, for example, tungsten (W), copper (Cu), and aluminum (Al).

The cell interconnection lines 1855 may be connected to the studs 180. However, in example embodiments, the number of layers and arrangement shape of the plugs and interconnection lines included in the cell interconnection structure may be variously changed. The cell interconnection lines 1855 may be formed of a conductive material, and may include, for example, at least one of tungsten (W), aluminum (Al), or copper (Cu).

The first bonding vias 195 and the first bonding metal layers 198 may be disposed below a lowermost set of the cell interconnection lines 1855. The first bonding vias 195 may connect the cell interconnection lines 1855 and the first bonding metal layers 198, and the first bonding metal layers 198 may be bonded to and connected to the second bonding metal layers 298 of the second semiconductor structure S2. The first bonding insulating layer 199 may be bonded and connected to the second bonding insulating layer 299 of the second semiconductor structure S2. The first bonding vias 195 and the first bonding metal layers 198 may include a conductive material, and may include, for example, copper (Cu). The first bonding insulating layer 199 may include, for example, at least one of SiO, SiN, SiCN, SiOC, SiON, or SiOCN.

The first and second semiconductor structures S1 and S2 may be bonded by bonding of the first bonding metal layers 198 and the second bonding metal layers 298 and bonding of the first bonding insulating layer 199 and the second bonding insulating layer 299. The bonding of the first bonding metal layers 198 and the second bonding metal layers 298 may be, for example, copper (Cu)-to-copper (Cu) bonding, and the bonding of the first bonding insulating layer 199 and the second bonding insulating layer 299 may be, for example, dielectric-dielectric bonding, such as SiCN-to-SiCN bonding. The first and second semiconductor structures S1 and S2 may be bonded by hybrid bonding including copper (Cu)-to-copper (Cu) bonding and dielectric-to-dielectric bonding.

The passivation layer 106 may be disposed on the upper surface of the plate layer 101 and may protect a semiconductor device 10d. The passivation layer 106 may include an insulating material, and may include, for example, at least one of silicon oxide, silicon nitride, or silicon carbide. The substrate insulating layer 121 may be widely disposed in the first region R1 and the second region R2 to cover upper ends of the contact plugs 170, an upper end of a through-plug 164, and upper ends of the capacitor contacts 165. However, in example embodiments, an arrangement shape of the substrate insulating layer 121 may be variously changed within a range electrically separating the contact plugs 170, the through-plugs 164, and the capacitor contacts 165 from the plate layer 101.

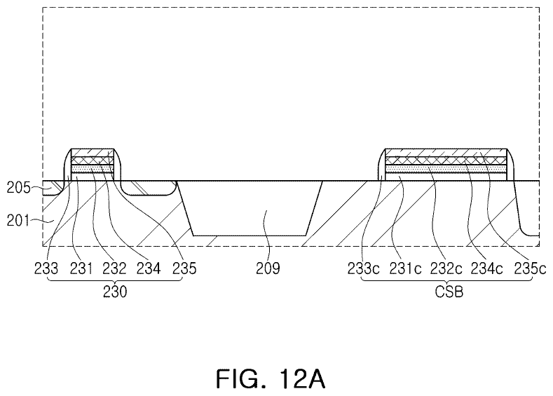

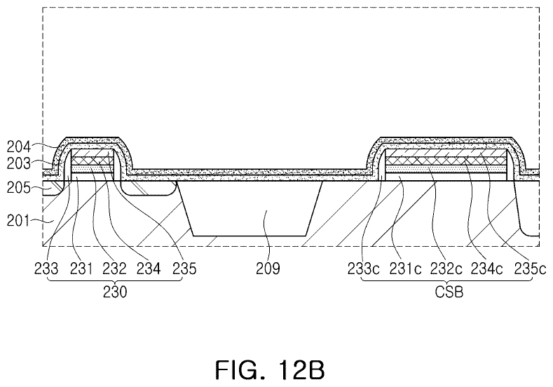

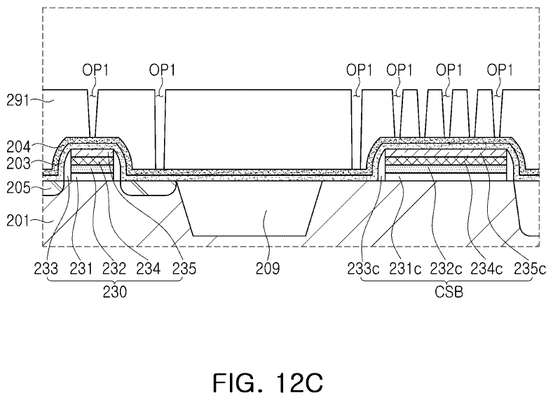

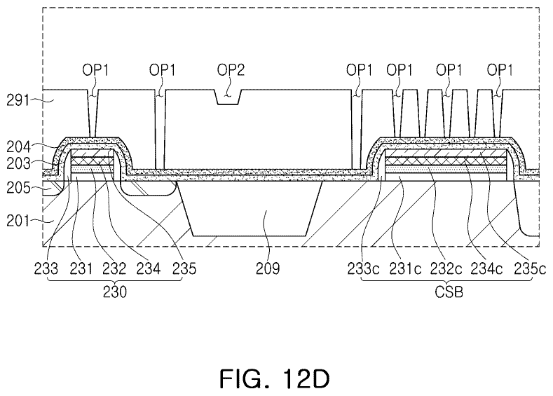

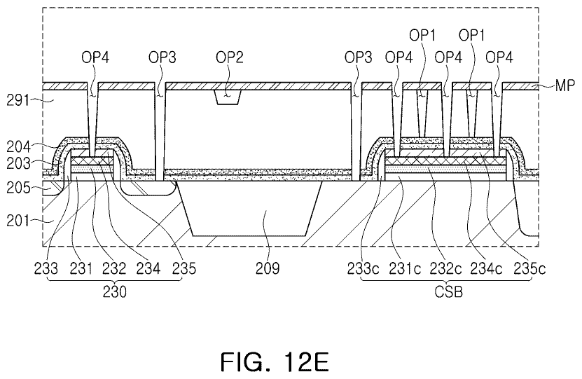

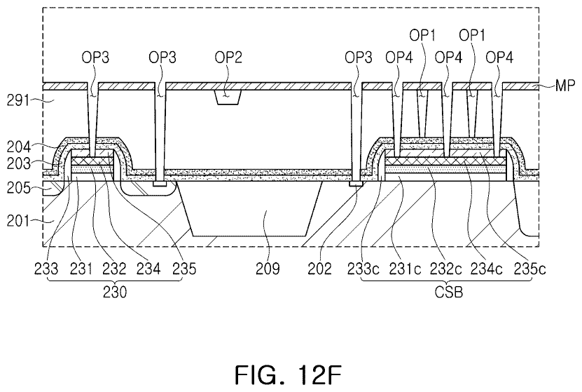

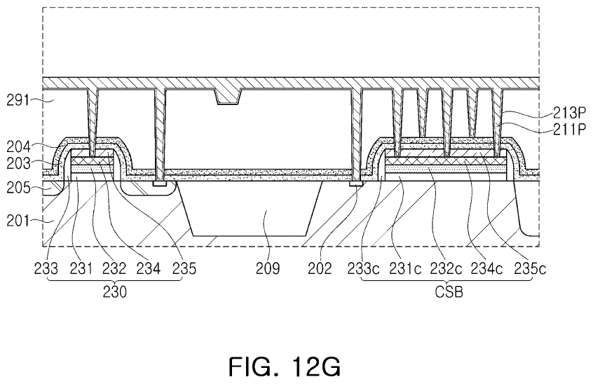

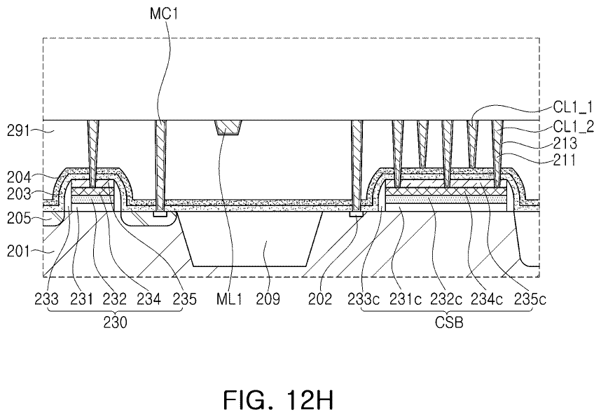

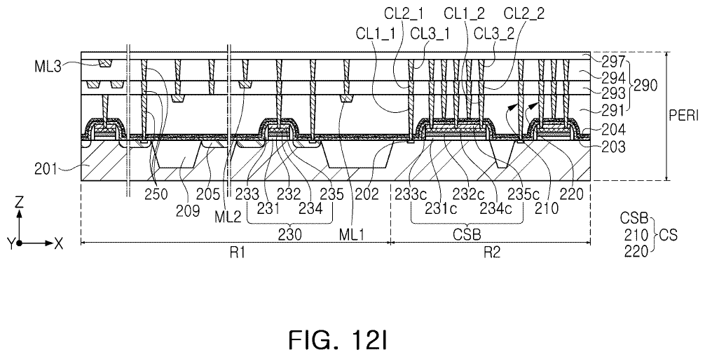

FIGS. 12A to 12I are views illustrating an example embodiment of a method of manufacturing a semiconductor device of FIG. 2. FIGS. 12A to 12H illustrate cross-sectional views corresponding to an enlarged cross-sectional view of the semiconductor device 10 of FIG. 4, and FIG. 12I illustrates a cross-sectional view corresponding to a cross-sectional view of the semiconductor device 10 of FIG. 2.

Referring to FIG. 12A, the method of manufacturing a semiconductor device may include an operation of forming an element isolation region 209, peripheral circuit elements 230, and a capacitor base structure CSB within a substrate 201.

The element isolation region 209 may be formed within the substrate 201. The element isolation region 209 may define an active region of each peripheral circuit element 230, and may define each capacitor region CA within a second region R2.

The element isolation region 209 may be formed through a shallow trench isolation (STI) process. The shallow trench isolation process may be a process of forming isolation trenches within the substrate 201 and filling the isolation trenches with an insulating material such as silicon oxide.

When the element isolation region 209 is formed within the substrate 201, the gate dielectric layer 231, the first gate electrode 232, the second gate electrode 234, and the gate capping layer 235 may be sequentially formed throughout the substrate 201, and the stack structure may be removed except for a region in which the gate structure of each peripheral circuit element 230 and the capacitor base structure CSB are formed.

Gate spacers 233 and base spacers 233c may be formed on both (e.g., opposite) sidewalls of the gate structure formed in this manner and on sidewalls of the capacitor base structure CSB. Next, an ion implantation process may be performed, so that an impurity region 205, which is a source/drain region, may be formed within the substrate 201 on both sides (e.g., opposite sides) of each gate structure. As a result, the peripheral circuit elements 230 may be completed.

As in FIG. 12B, on a front surface of the substrate 201 on which peripheral circuit elements 230 and a capacitor base structure CSB are formed, the substrate 201 may be heat-treated to form a first substrate insulating layer 203 such as silicon oxide or silicon oxycarbide. The first substrate insulating layer 203 may be formed conformally along the shape of each element 230 formed on an upper portion of the substrate 201.

A second substrate insulating layer 204 may be formed on the first substrate insulating layer 203. The second substrate insulating layer 204 may include a different material to have etching selectivity from the first substrate insulating layer 203, and may include, for example, silicon nitride.

The second substrate insulating layer 204 may be stacked to have a thickness greater than that of the first substrate insulating layer 203, but the present invention is not limited thereto.

As illustrated in FIG. 12C, the first peripheral capping insulating layer 291 may be formed to cover an entire surface of the substrate 201, and first openings OP1 may be formed.

The first openings OP1 may be formed from an upper surface of the first peripheral capping insulating layer 291. The first openings OP1 may be etched using the second substrate insulating layer 204 as an etching stopper to form first contact plugs MC1 around the peripheral circuit elements 230. In this case, first openings OP1 for forming both the contact plugs MC1 connected to the gate electrode 234 on the gate structure and the contact plugs MC1 connected to the source/drain may be formed at the same time. Accordingly, the first openings OP1 may be formed so as to expose the upper surface of the second substrate insulating layer 204 in a region in which each contact structure is disposed.

In this case, in the second region R2, line-type first openings OP1 extending in the Y-direction may be formed in a region corresponding to the first subsidiary capacitor electrodes CL1_1 and CL1_2 in the first and second electrode structures 210 and 220. The first openings OP1 of the second region R2 may also be etched using the second substrate insulating layer 204 as an etching stopper until the second substrate insulating layer 204 is exposed.

Accordingly, a set of the first opening OP1 corresponding to the first contact electrode structure 210C may be formed to expose the second substrate insulating layer 204 on a separation region, and the remaining first openings OP1 may be formed to expose the second substrate insulating layer 204 on the capacitor base structure CSB.

As in FIG. 12D, second openings OP2 may be further formed in the region in which the first interconnection lines ML1 are formed on the first peripheral capping insulating layer 291. The formation of the second openings OP2 may define the connection portion MLC and the contact interconnection lines MLL of FIG. 3, FIG. 6B and FIG. 7 together, and may be etched to a shallower depth than the first openings OP1.

When the second opening OP2 is formed within the first opening OP1 in the capacitor region CA, an opening may have a shape further expanded from an upper portion thereof, but the present invention is not limited thereto. For example, a side surface may be formed to have a continuous inclination.

As illustrated in FIG. 12E, a mask pattern MP may be formed to expose only the first openings OP1 corresponding to the first contact electrode structure 210C and the second electrode structures 220 within the capacitor region CA, among the first openings OP1, and the exposed first openings OP1 may be etched back to form a third opening OP3 so that a region corresponding to the first contact electrode structure 210C exposes the substrate 201, and the first openings OP1 corresponding to the second electrode structure 220 may be etched back to form fourth openings OP4 exposing the second base conductive layer 234c, respectively. Accordingly, a level of a lower end of the first electrode structures 210 and the second electrode structures 220 illustrated in FIGS. 2 and 4 may be formed.

Additionally, the first openings OP1 corresponding to the second gate electrode 234 and the impurity region 205 may be etched back to form fourth openings OP4 and third openings OP3.

As illustrated in FIG. 12F, high concentration impurities may be injected into the substrate 201 exposed by the third opening OP3, and a resistance mitigating layer 202 may be formed to reduce the contact resistance. In this case, when the substrate 201 has an N-type, N-type impurities may be injected, and when the substrate 201 has a P-type, P-type impurities may be injected, but the present invention is not limited thereto.

In this case, a resistance mitigating layer 202 may also be formed together in a region corresponding to the contact plug MC1 in contact with the impurity region 205 which is a source and/or drain region. When the resistance mitigating layer 202 is formed, a cleaning process, for example, plasma etching, may be performed, but the present invention is not limited thereto.

As in FIG. 12G, an operation of forming first and second lower subsidiary capacitor electrodes CL1_1 and CL1_2 may be included.

The first and second lower subsidiary capacitor electrodes CL1_1 and CL1_2 may be formed to have a plate shape alternating in the X-direction and extending in the Y-direction and the Z-direction. In one example, the first and second lower subsidiary capacitor electrodes CL1_1 and CL1_2 may be formed by a damascene process.

For example, a preliminary diffusion barrier 213P may be conformally formed on an exposed surface within each of the exposed openings OP1, OP2, OP3 and OP4.

A preliminary conductive material 211P may be overdeposited over the preliminary diffusion barrier 213P to cover the first peripheral capping insulating layer 291.

Next, as illustrated in FIG. 12H, chemical mechanical polishing (CMP) may be performed until the upper surface of the first peripheral capping insulating layer 291 is exposed, thereby forming buried interconnection structures. By this dual damascene process, the first and second lower subsidiary capacitor electrodes CL1_1 and CL1_2 of the first and second electrode structures 210 and 220 of the capacitor structure CS may be formed.

Referring to FIG. 12I, a second peripheral capping insulating layer 293 may be formed, and a dual damascene process may be performed to form first and second intermediate subsidiary capacitor electrodes CL2_1 and CL2_2 together with second interconnection lines MC2 and ML2, and a third peripheral capping insulating layer 294 may be formed, and a dual damascene process may be performed to form first and second upper subsidiary capacitor electrodes CL3_1 and CL3_2 together with third interconnection lines MC3 and ML3.

Through such a process, the first electrode structure 210 and the second electrode structure 220 may be formed to have different lengths, and may have a structure further extending downwardly within the first peripheral capping insulating layer 291 to have the largest possible capacitance.

An upper surface of the third peripheral capping insulating layer 294 may be covered and the fourth peripheral capping insulating layer 297 may be formed, thereby completing a peripheral circuit structure PERI.

A memory cell structure CELL may be formed on the peripheral circuit structure PERI as in FIG. 2, thereby completing the manufacturing of the semiconductor device 10 of FIG. 2.

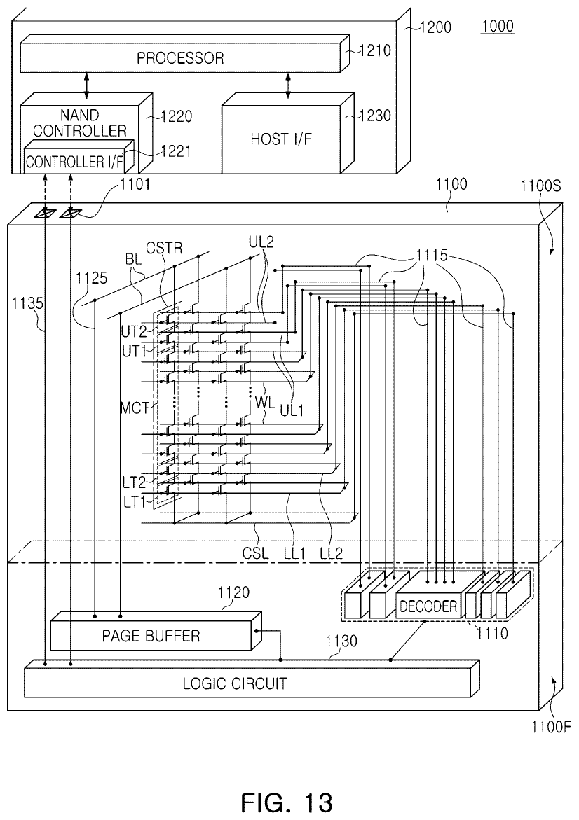

FIG. 13 is a view schematically illustrating a data storage system including a semiconductor device according to example embodiments of the present disclosure.

Referring to FIG. 13, a data storage system 1000 may include a semiconductor device 1100 and a controller 1200 electrically connected to the semiconductor device 1100. The data storage system 1000 may be a storage device including one or more semiconductor devices 1100 or an electronic device including the storage device. For example, the data storage system 1000 may be a solid state drive device (SSD), a Universal Serial Bus (USB), a computing system, a medical device, or a communication device, which include one or more semiconductor devices 1100.

The semiconductor device 1100 may be a nonvolatile memory device, for example, a NAND flash memory device as described above with reference to FIGS. 1A to 5. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed depending on the example embodiments.

In example embodiments, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In example embodiments, the lower transistors LT1 and LT2 may include a lower erase control transistor LT1 and a ground select transistor LT2 serially connected to each other. The upper transistors UT1 and UT2 may include a string select transistor UT1 and an upper erase control transistor UT2 serially connected to each other. At least one of the lower erase control transistor LT1 and the upper erase control transistor UT2 may be used for an erase operation of erasing data stored in the memory cell transistors MCT by utilizing a GIDL phenomenon.

The common source line CSL, the first and second gate lower lines LL1 and LL2, the word lines WL, and the first and second gate upper lines UL1 and UL2 may be electrically connected to the decoder circuit 1110 through first interconnection lines 1115 extending from the first structure 1100F to the second structure 1100S. The bit lines BL may be electrically connected to the page buffer 1120 through second interconnection lines 1125 extending from the first structure 1100F to the second structure 1100S.

In the first structure 1100F, the decoder circuit 1110 and the page buffer 1120 may execute a control operation for at least one selected memory cell transistor, among a plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output interconnection line 1135 that extends from the first structure 1100F to the second structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may control the NAND controller 1220 to access the semiconductor device 1100. The NAND controller 1220 may include a controller interface 1221 processing communication with the semiconductor device 1100. Through the controller interface 1221, control commands for controlling the semiconductor device 1100, data to be written to the memory cell transistors MCT of the semiconductor device 1100, data to be read from the memory cell transistors MCT of the semiconductor device 1100, and the like, may be transmitted. The host interface 1230 may provide a communication function between the data storage system 1000 and an external host. When a control command is received from the external host through the host interface 1230, the processor 1210 may control the semiconductor device 1100 in response to the control command.

While example embodiments have been illustrated and described above, it will be apparent to those skilled in the art that modifications and variations could be made within a scope not departing from the spirit and region of the present disclosure as defined by the appended claims.

What is claimed is:

1. A semiconductor device, comprising:
a peripheral circuit structure including a substrate, an active region within the substrate, transistors on the substrate, an element isolation region defining the active region, a capping insulating layer covering the transistors, an interconnection wiring electrically connected to the transistors, and a capacitor spaced apart from the interconnection wiring in a first direction; and
a memory cell structure including a plate layer disposed on the peripheral circuit structure, gate electrodes sequentially stacked on the plate layer and spaced apart from each other in a second direction, perpendicular to an upper surface of the plate layer, and vertical channel structures penetrating through the gate electrodes and extending in the second direction,
wherein:
the capacitor includes:
a capacitor base disposed on the substrate and having multiple layers,
first capacitor electrodes having a plate shape extending in a third direction intersecting the first direction, and in the second direction, and
second capacitor electrodes, each having a plate shape extending in the second direction and the third direction and disposed alternately with the first capacitor electrodes in the first direction,
wherein lower ends of the second capacitor electrodes are disposed to penetrate partially through the capacitor base, and
the first capacitor electrodes penetrate through the capping insulating layer so that lower ends of capacitor electrodes of a set of the first capacitor electrodes are disposed at a level higher than an upper surface of the capacitor base.

2. The semiconductor device of claim 1,
wherein the peripheral circuit structure further includes:
a first substrate insulating layer covering the transistors, the capacitor base and the substrate, and
a second substrate insulating layer covering the first substrate insulating layer and including a different material from the first substrate insulating layer.

3. The semiconductor device of claim 2,
wherein the lower ends of capacitor electrodes of the set of the first capacitor electrodes are in contact with the second substrate insulating layer.

4. The semiconductor device of claim 2,
wherein the lower ends of capacitor electrodes of the set of the first capacitor electrodes are in contact with the second substrate insulating layer and are disposed at a level higher than an upper surface of the first substrate insulating layer.

5. The semiconductor device of claim 2,
wherein the capacitor base further includes a dielectric layer having higher dielectric constant than that of the first substrate insulating layer below the second substrate insulating layer.

6. The semiconductor device of claim 1,
wherein the capping insulating layer includes a plurality of capping insulating layers, and
each capacitor electrode of the set of the first capacitor electrodes and the second capacitor electrodes includes subsidiary capacitor electrodes respectively penetrating through the plurality of capping insulating layers, extending along the second direction, and forming the plate shape.

7. The semiconductor device of claim 6,
wherein a length of first lower subsidiary capacitor electrodes of the set of the first capacitor electrodes penetrating through a lowermost capping insulating layer, among the plurality of capping insulating layers, and a length of second lower subsidiary capacitor electrodes of the second capacitor electrodes penetrating through the lowermost capping insulating layer are different from each other.

8. The semiconductor device of claim 6,
wherein each of the transistors includes:
a gate dielectric layer on the substrate,
a gate electrode layer on the gate dielectric layer, and
a gate capping layer on the gate electrode layer, and
the capacitor base includes:
a base dielectric layer including the same material as the gate dielectric layer on the substrate,
a base conductive layer including the same material as the gate electrode layer on the base dielectric layer, and
a base capping layer including the same material as the gate capping layer on the base conductive layer.

9. The semiconductor device of claim 8,
wherein the lower ends of the second capacitor electrodes extend to contact an upper surface of the base conductive layer.

10. The semiconductor device of claim 6, wherein:
each of the subsidiary capacitor electrodes of the set of the first capacitor electrodes has a first top end,
each of the subsidiary capacitor electrodes of the second capacitor electrodes has a second top end,
the plurality of capping insulating layers has a lowermost capping insulating layer, and
a first length from the first top end to an upper surface of the lowermost capping insulating layer is the same as a second length from the second top end to the upper surface of the lowermost capping insulating layer.

11. The semiconductor device of claim 1,
wherein each capacitor electrode of the set of the first capacitor electrodes is spaced apart from an adjacent one of the second capacitor electrodes by the same distance in the first direction.

12. The semiconductor device of claim 1,
wherein the first capacitor electrodes include:
a first contact electrode spaced apart from the capacitor base and extending from the substrate, and
first remaining capacitor electrodes.

13. The semiconductor device of claim 12, wherein:
the second capacitor electrodes include:
a second outmost capacitor electrode among the second capacitor electrodes, which is closest to the first contact electrode, and
second remaining capacitor electrodes,
a first separation distance is a distance between the first contact electrode and the second outmost capacitor electrode,
a second separation distance is a distance between one of first remaining capacitor electrodes and an adjacent one of the second remaining capacitor electrodes, and
the first separation distance is greater than the second separation distance.

14. A semiconductor device, comprising:
a substrate including an active region;
transistors including a gate structure on the active region, the gate structure including a plurality of stacked layers;
an element isolation region defining the active region and defining a capacitor region;
a substrate insulating layer covering the transistors and the element isolation region;
a plurality of capping insulating layers covering the substrate insulating layer and having a flat upper surface; and
a capacitor disposed within the capacitor region defined by the element isolation region and penetrating through the plurality of capping insulating layers,
wherein the capacitor includes:
a capacitor base extending in a first direction and a second direction, intersecting the first direction, and having the same plurality of stacked layers as the gate structure,
first capacitor electrodes having a plate shape extending in the second direction and a third direction, the third direction intersecting the first direction and the second direction, and
second capacitor electrodes having the plate shape extending in the second direction and the third direction, and disposed alternately with the first capacitor electrodes in the first direction,
wherein lower ends of the second capacitor electrodes are disposed to penetrate partially through the capacitor base, and
wherein lower ends of a set of the first capacitor electrodes penetrate through a lowermost capping insulating layer, among the plurality of capping insulating layers, and extend to contact the substrate insulating layer.

15. The semiconductor device of claim 14,
wherein a length of the set of first capacitor electrodes in the third direction is shorter than a length of the second capacitor electrodes in the third direction.

16. The semiconductor device of claim 14, further comprising a first contact electrode spaced apart from the capacitor base and extending from the substrate.

17. The semiconductor device of claim 16,
wherein a length of the first contact electrode in the third direction within the lowermost capping insulating layer is longer than a length of the second capacitor electrodes in the third direction within the lowermost capping insulating layer.

18. The semiconductor device of claim 16,wherein:
the second capacitor electrodes include:
a second outmost capacitor electrode among the second capacitor electrodes, which is closest to the first contact electrode, and
second remaining capacitor electrodes,
a first separation distance is a distance between the first contact electrode and the second outmost capacitor electrode,
a second separation distance is a distance between one of first remaining capacitor electrodes and an adjacent one of the second remaining capacitor electrodes, and
the first separation distance is greater than the second separation distance.

19. A semiconductor device, comprising:
a substrate including an active region;
a gate structure on the active region;
a source/drain region disposed on each of two opposite sides of the gate structure within the active region;
an element isolation region defining the active region and defining a capacitor region;
a substrate insulating layer covering the gate structure and the element isolation region;
a plurality of capping insulating layers covering the substrate insulating layer and having a flat upper surface, the plurality of capping insulating layers including a lowermost capping insulating layer;
a first contact plug contacting the gate structure, and a second contact plug contacting the source/drain region, and the first and second contact plugs disposed within the lowermost capping insulating layer; and
a capacitor disposed within the capacitor region defined by the element isolation region, and penetrating through the plurality of capping insulating layers,
wherein the capacitor includes:
a capacitor base extending in a first direction and a second direction intersecting the first direction, and having the same plurality of stacked layers as the gate structure,
first capacitor electrodes having a plate shape extending in the second direction and in a third direction perpendicular to the first direction and the second direction, and
second capacitor electrodes having the plate shape extending in the second direction and the third direction and disposed alternately with the first capacitor electrodes in the first direction,
wherein lower ends of the second capacitor electrodes are disposed at the same level as lower ends of the first contact plugs,
wherein a lower end of a first contact electrode, among the first capacitor electrodes, is disposed at the same level as a lower end of the second contact plug, and
wherein a lower end of a second contact pattern, among the first capacitor electrodes, penetrates through the lowermost capping insulating layer, on the capacitor base, and extends to contact the substrate insulating layer.

20. The semiconductor device of claim 19,
wherein a set of the first capacitor electrodes and the second capacitor electrodes penetrate through at least a portion of the lowermost capping insulating layer and extend in the third direction,
wherein each capacitor electrode of the set of the first capacitor electrodes has first and second sidewalls facing away from each other,
wherein each of the second capacitor electrodes has third and fourth sidewalls facing away from each other, and
wherein, in the first direction, at least one of the first and second sidewalls of each capacitor electrode of the set of the first capacitor electrodes faces at least one of the third and fourth sidewalls of each of the second capacitor electrodes.
